(19) United States
(12) Patent Application Publication
(10) Pub. No.: US 2023/0238344 A1
(43) Pub. Date: Jul. 27, 2023

(54) ELECTRONIC DEVICE AND METHOD FOR MANUFACTURING SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Tomohiro SAITO, Yokohama Kanagawa (JP)

(21) Appl. No.: 17/888,915

(22) Filed: Aug. 16, 2022

(30) Foreign Application Priority Data
Jan. 25, 2022 (JP) 2022-009599

(51) Int. Cl. H01L 23/00

(52) U.S. Cl. CPC H01L 24/13; H01L 24/16; H01L 24/81; H01L 2224/13076; H01L 2224/13144; H01L 2224/13124; H01L 2224/13147; H01L 2224/13109; H01L 2224/13184; H01L 2224/13166; H01L 2224/13164; H01L 2224/13188; H01L 2224/16145; H01L 2924/05442; H01L 2924/05042; H01L 2924/04941; H01L 2924/1306; H01L 2924/1461; H01L 2924/1436; H01L 2924/12041; H01L 2924/12042; H01L 2224/81193; H01L 2224/81201

(57) ABSTRACT

An electronic device includes a first structure body and a second structure body. The first structure body includes a first base body, a first bonding electrode and a first hard part. The second structure body includes a second base body, and a second bonding electrode. The first bonding electrode and the second bonding electrode are bonded to each other between the first base body and the second base body. The first hard part is located between the first base body and the second base body. The first hard part is positioned within an area in which the first bonding electrode is located when viewed along a first direction. The first direction is from the first base body toward the first bonding electrode. The first hard part has a higher hardness than the first bonding electrode.

### CROSS-REFERENCE TO RELATED APPLICATIONS

This application is based upon and claims the benefit of priority from Japanese Patent Application No. 2022-009599, filed on Jan. 25, 2022; the entire contents of which are incorporated herein by reference.

### FIELD

Embodiments relate to an electronic device and a method for manufacturing same.

### BACKGROUND

There is an electronic device in which multiple structure bodies are bonded to each other. According to a method for manufacturing such an electronic device, bonding electrodes that are included in the structure bodies are bonded to each other. It is desirable to increase the yield of such an electronic device.

### BRIEF DESCRIPTION OF THE DRAWINGS

FIGS. 1A to 1C are schematic views illustrating the electronic device according to an embodiment;

FIGS. 2A to 2C are schematic views illustrating another electronic device according to the embodiment;

FIGS. 3A to 3C are schematic views illustrating another electronic device according to the embodiment;

FIGS. 4A to 4C are schematic views illustrating another electronic device according to the embodiment;

FIG. 5 is a schematic cross-sectional view illustrating another electronic device according to the embodiment;

FIGS. 6A and 6B are schematic views illustrating another electronic device according to the embodiment;

FIGS. 7A to 7C are schematic views illustrating another electronic device according to the embodiment;

FIGS. 8A to 8C are schematic views illustrating another electronic device according to the embodiment;

FIGS. 9A and 9B are schematic views illustrating another electronic device according to the embodiment;

FIGS. 10A to 10C are schematic views illustrating another electronic device according to the embodiment;

FIG. 11 is a schematic plan view illustrating another electronic device according to the embodiment;

FIGS. 12A to 12F are schematic views illustrating the method for manufacturing the electronic device according to the embodiment;

FIG. 13A and FIG. 13B are schematic views illustrating the method for manufacturing the electronic device according to the embodiment;

FIGS. 14A and 14B are schematic views illustrating a method for manufacturing another electronic device according to the embodiment;

FIGS. 15A to 15C are schematic views illustrating a method for manufacturing another electronic device according to the embodiment;

FIGS. 16A and 16B are schematic views illustrating a method for manufacturing another electronic device according to the embodiment;

FIGS. 17A to 17C are schematic views illustrating a method for manufacturing another electronic device according to the embodiment;

FIGS. 18A to 18C are schematic views illustrating a method for manufacturing another electronic device according to the embodiment;

FIGS. 19A to 19C are schematic views illustrating a method for manufacturing another electronic device according to the embodiment;

FIGS. 20A to 20C are schematic views illustrating a method for manufacturing another electronic device according to the embodiment;

FIG. 21 is a schematic cross-sectional view illustrating another electronic device according to the embodiment; and

FIG. 22 is a schematic cross-sectional view illustrating another electronic device according to the embodiment.

### DETAILED DESCRIPTION

An electronic device according to one embodiment, includes a first structure body and a second structure body. The first structure body includes a first base body, a first wiring part, a first bonding electrode and a first hard part. The first wiring part is located at the first base body. The first bonding electrode is electrically connected with the first wiring part. The second structure body includes a second base body, a second wiring part, and a second bonding electrode. The second wiring part is located at the second base body. The second bonding electrode is electrically connected with the second wiring part. The first bonding electrode and the second bonding electrode are bonded to each other between the first base body and the second base body. The first hard part is located between the first base body and the second base body. The first hard part is positioned within an area in which the first bonding electrode is located when viewed along a first direction. The first direction is from the first base body toward the first bonding electrode. The first hard part has a higher hardness than the first bonding electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

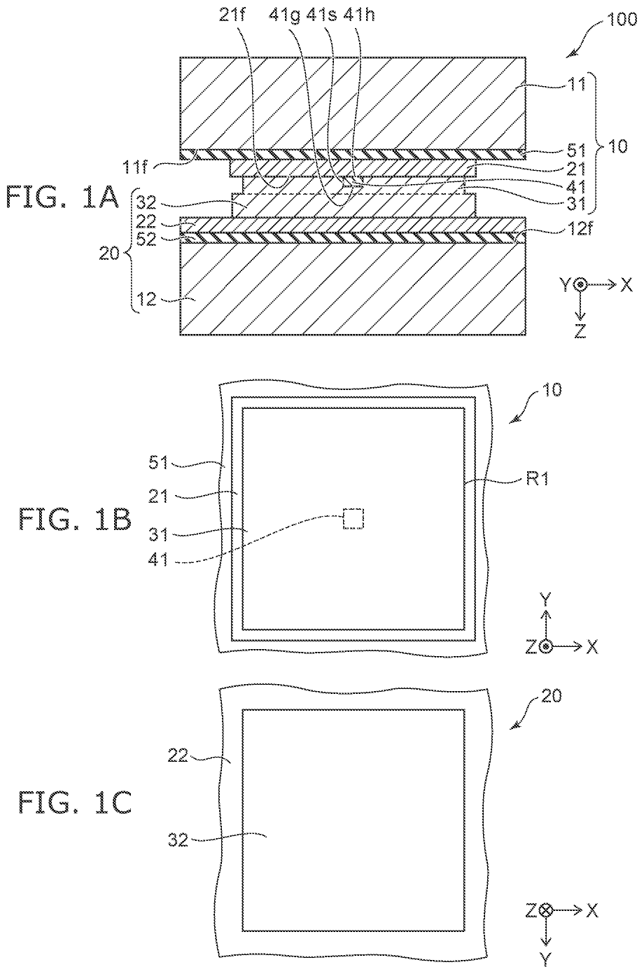

Embodiments of the invention relate to an electronic device (an electrical device). For example, the electronic device is operated by electrical power or utilizes an electrical signal. For example, a semiconductor device is an example of the electronic device. According to the following embodiments, the electronic device may be, for example, a semiconductor device. FIGS. 1A to 1C are schematic views illustrating the electronic device according to the embodiment.

FIG. 1A is a schematic cross-sectional view illustrating the electronic device 100 according to the embodiment. As illustrated in FIG. 1A, the electronic device 100 includes a first structure body 10 and a second structure body 20. FIG. 1B is a schematic plan view illustrating the first structure body 10. FIG. 1C is a schematic plan view illustrating the second structure body 20.

The first structure body 10 includes a first base body 11, a first wiring part 21, a first bonding electrode 31, and a first hard part 41. The first structure body 10 may include a first insulating film 51.

The second structure body 20 includes a second base body 12, a second wiring part 22, and a second bonding electrode 32. The second structure body 20 may include a second insulating film 52.

In the description of the embodiments, the direction from the first base body 11 toward the first bonding electrode 31 is taken as a Z-direction. One direction perpendicular to the Z-direction is taken as an X-direction. A direction perpendicular to the Z-direction and the X-direction is taken as a Y-direction. The Z-direction is the direction from the first base body 11 toward the second base body 12. The Z-direction is the stacking direction of the first and second structure bodies 10 and 20.

The first base body 11 includes a semiconductor. Specifically, the first base body 11 includes, for example, at least one of silicon or a compound semiconductor (e.g., SiC, GaN, etc.). The first base body 11 includes, for example, a semiconductor substrate. The substrate may be a wafer or a chip. The first base body 11 is, for example, a silicon substrate. However, according to embodiments, the first base body 11 is not limited to a substrate. The first base body 11 may be a portion of a wafer or chip.

The first wiring part 21 (the conductive part) is located at the first base body 11. The first wiring part 21 may include multiple interconnects. A portion of the first wiring part 21 is located at a first surface 11f side of the first base body 11. For example, the first wiring part 21 includes at least one selected from the group consisting of Al, AlCu, AlSiCu, Ti, TiN, Cu, TaN, W, and alloys of these materials. The first wiring part may include multiple wiring layers.

In the example, the first insulating film 51 is located at the first surface 11f. A portion of the first insulating film 51 is positioned between the first wiring part 21 and the first base body 11. The first insulating film 51 includes, for example, at least one of silicon oxide, silicon nitride, or polyimide.

The first bonding electrode 31 is electrically connected with the first wiring part 21. The first bonding electrode 31 contacts the first wiring part 21 at the first surface 11f side of the first base body 11. The first bonding electrode 31 includes, for example, a ductile metal. Specifically, the first bonding electrode 31 includes, for example, at least one selected from the group consisting of gold (Au), aluminum (Al), copper (Cu), and iridium (Ir). It is desirable for the material of the first bonding electrode 31 to be ductile and to have low electrical resistance. The first bonding electrode 31 may include multiple stacked conductive layers.

The first hard part 41 is located between the first base body 11 and the second base body 12 (or the second bonding electrode 32). In the example, the first hard part 41 is located between the first base body 11 and the first bonding electrode 31 (more specifically, between the first wiring part 21 and the first bonding electrode 31). For example, a surface 41h of the first hard part 41 at the first base body 11 side contacts a surface 21f of the first wiring part 21 at the second base body 12 side.

As illustrated in FIG. 1B, the first hard part 41 is positioned within an area R1 in which the first bonding electrode 31 is located in a plane perpendicular to the Z-direction. For example, the entire first hard part 41 overlaps the first bonding electrode 31 and is not located outside the area R1 when viewed along the Z-direction. The area R1 is surrounded with the outer perimeter of one bonding electrode 31 when viewed along the Z-direction. In the example, the area R1 is a rectangular region. The shape of the first bonding electrode 31, the shape of the second bonding electrode 32, and the shape of the first hard part 41 are not limited to rectangular and may be circular, polygonal, etc.

In the example illustrated in FIGS. 1A and 1B, the first hard part 41 is positioned at the central part of the area R1, is covered with the first bonding electrode 31, and is enclosed with the first bonding electrode 31. For example, four side surfaces 41s of the first hard part 41 and a surface 41g of the first hard part 41 at the second base body 12 side contact the first bonding electrode 31. However, the position of the first hard part 41 is not limited thereto; for example, the first hard part 41 may be located at an end portion of the area R1. The surface 41g also may contact the second bonding electrode 32.

As illustrated in FIG. 1B, the planar shape of the first hard part 41 is rectangular. However, the planar shape of the first hard part 41 is not limited thereto and is arbitrary. Multiple first hard parts 41 may be located within one area R1. In the example of FIG. 1A, the surface 41g is a plane extending along the X-Y plane. However, the shape of the first hard part 41 is not limited thereto and is arbitrary. For example, the first hard part 41 may include a curved surface or may be conical or frustum-shaped.

The hardness (or rigidity) of the first hard part 41 is greater than the hardness (or rigidity) of the first bonding electrode 31. That is, the first hard part 41 includes a material having a higher hardness than the material of the first bonding electrode 31. The Young's modulus or Vickers hardness may be used as the index of the hardness (or rigidity). For example, the Young's modulus of the material of the first hard part 41 is greater than the Young's modulus of the material of the first bonding electrode 31. For example, the Vickers hardness of the material of the first hard part 41 is greater than the Vickers hardness of the material of the first bonding electrode 31.

The first hard part 41 includes, for example, a brittle material. The first hard part 41 includes, for example, at least one selected from the group consisting of aluminum, tungsten, titanium, palladium, nitrides of such elements, alloys of such elements, oxides of such elements, and an insulating film of silicon oxide, silicon nitride, or the like. More specifically, the first hard part 41 can include, for example, at least one of a TEOS (tetraethyl orthosilicate) film, a silicon oxide film, a silicon nitride film, a metal film (a conductive film) that includes titanium nitride or the like, a silicide film that includes tungsten silicide, etc. Thus, the first hard part 41 may be an insulating film or a metal film, and it is sufficient for the first hard part 41 to have a higher hardness (or rigidity) than the first bonding electrode 31.

The hardness (or rigidity) of the first hard part 41 may be greater than the hardness (or rigidity) of the second bonding electrode 32. That is, the first hard part 41 may include a material having a higher hardness than the material of the second bonding electrode 32.

The second base body 12 includes a semiconductor. Specifically, the second base body 12 includes, for example, at least one of silicon or a compound semiconductor. The second base body 12 includes, for example, a semiconductor substrate. The second base body 12 is, for example, a silicon substrate. However, according to the embodiment, the second base body 12 is not limited to a substrate. The second base body 12 may be a portion of a wafer or chip.

The second wiring part 22 (the conductive part) is located at the second base body 12. The second wiring part 22 may include multiple interconnects. A portion of the second wiring part 22 is located at a second surface 12f side of the second base body 12. For example, the second wiring part 22 includes at least one selected from the group consisting of Al, AlCu, AlSiCu, Ti, TiN, Cu, TaN, W, and alloys of these materials. The second wiring part may include multiple wiring layers.

In the example, the second insulating film 52 is located at the second surface 12f. A portion of the second insulating film 52 is positioned between the second wiring part 22 and the second base body 12. The second insulating film 52 includes, for example, at least one of silicon oxide, silicon nitride, or polyimide.

The second bonding electrode 32 is electrically connected with the second wiring part 22. The second bonding electrode 32 contacts the second wiring part 22 at the second surface 12f side of the second base body 12. The second bonding electrode 32 includes, for example, a ductile metal. Specifically, the second bonding electrode 32 includes, for example, at least one selected from gold (Au), aluminum (Al), copper (Cu), and iridium (Ir). The second bonding electrode 32 may include multiple stacked conductive layers.

The first bonding electrode 31 and the second bonding electrode 32 are bonded to each other between the first base body 11 and the second base body 12. The bonding includes, for example, compression bonding. However, the bonding is not limited to compression bonding and may be any method that can bond the bonding electrodes to each other. For example, in thermal compression bonding, the bonding is performed by compression-bonding while applying heat, or by applying heat after compression-bonding.

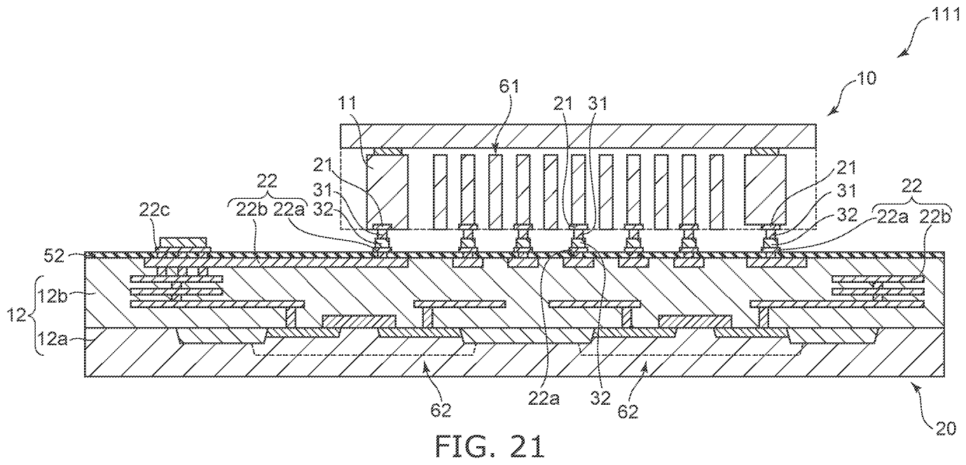

As described below, the first structure body 10 may include a first element part 61 (e.g., see FIG. 21). The second structure body 20 may include a second element part 62 (e.g., see FIG. 21). The first element part 61 is electrically connected with the first wiring part 21. The second element part 62 is electrically connected with the second wiring part 22. For example, the first structure body 10 and the second structure body 20 are wafers in which devices (elements and interconnects) are formed, or chips in which devices are formed.

The first element part 61 and the second element part 62 each independently include, for example, at least one of a transistor, an integrated circuit, a control electrode, a high frequency element, a sensor element, a memory element, a light-emitting element, or a light-receiving element. The transistor may be used for any purpose such as signal amplification, switching, power control, etc. For example, the control electrode controls or detects an electric field or a magnetic field. The sensor element is, for example, an element made using MEMS (Micro Electro Mechanical Systems) to detect an acceleration, a pressure, etc. The sensor element may be a strain gauge, a light-receiving element such as a photodiode, etc. The memory element is, for example, DRAM or nonvolatile memory. The light-emitting element is, for example, a semiconductor laser or a light-emitting diode. However, the first element part 61 and the second element part 62 are not limited thereto and may be any element that functions by being connected with wiring.

The first structure body 10 and the second structure body 20 are electrically connected by the bonding between the first bonding electrode 31 and the second bonding electrode 32. The input and output of electrical signals between the first structure body 10 and the second structure body 20 are possible via the first and second bonding electrodes 31 and 32. For example, the input and output of electrical signals are possible between the first element part 61 and the second element part 62.

According to the embodiment as described above, the first hard part 41 is included. For example, the occurrence of defects (e.g., open defects or short defects) of the bonding between the first bonding electrode 31 and the second bonding electrode 32 can be suppressed thereby. Accordingly, the yield of the electronic device can be increased.

For example, the first bonding electrode 31 and the second bonding electrode 32 are bonded to each other in a state in which the first bonding electrode 31 is pressed onto the second bonding electrode 32. Because the first hard part 41 that has a relatively high hardness is included, the first bonding electrode 31 can be sufficiently pressed onto the second bonding electrode 32 at this time, and the adhesion between the first bonding electrode 31 and the second bonding electrode 32 is easily improved. In other words, the contact pressure between the first bonding electrode 31 and the second bonding electrode 32 can be increased. The occurrence of open defects between the first bonding electrode 31 and the second bonding electrode 32 can be suppressed thereby.

Or, if the contact pressure between the bonding electrodes is too large, the distance between the base bodies may be reduced due to deformation of the bonding electrodes. In such a case, there is a possibility that the reduction of the distance between the base bodies may cause the bonding electrodes to deform and spread in in-plane directions (the X and Y-directions). Due to the deformation of the bonding electrodes, the bonding electrodes may contact other conductive parts (interconnects, etc.) located at the base body, thereby causing a short defect. In contrast, the first hard part 41 that has a relatively high hardness is less deformable than, for example, the first bonding electrode 31. Therefore, by using the first hard part 41 as a spacer or a stopper, the distance between the first base body 11 and the second base body 12 can be prevented from becoming too short. That is, the distance between the first base body 11 and the second base body 12 can be regulated by the first hard part 41. Deformation of the first and second bonding electrodes 31 and 32 can be suppressed thereby, and the occurrence of short defects can be suppressed.

In the example as described above, the first hard part 41 is located between the first bonding electrode 31 and the first wiring part 21. For example, the adhesion between the first bonding electrode 31 and the second bonding electrode 32 is easily improved thereby.

As illustrated in FIG. 1A, the X-direction length of the second bonding electrode 32 may be greater than the X-direction length of the first bonding electrode 31. For example, the effects of misalignment between the first bonding electrode 31 and the second bonding electrode 32 when bonding can be suppressed thereby. Similarly, the Y-direction length of the second bonding electrode 32 may be greater than the Y-direction length of the first bonding electrode 31. Conversely, the first bonding electrode 31 may be longer. For example, the X-direction length of the first bonding electrode 31 may be greater than the X-direction length of the second bonding electrode 32; and the Y-direction length of the first bonding electrode 31 may be greater than the Y-direction length of the second bonding electrode 32.

The boundary between the first bonding electrode 31 and the second bonding electrode 32 may not be clearly observable. In other words, the first bonding electrode 31 and the second bonding electrode 32 that are bonded to each other may be a conductive part that is formed to have a continuous body. In such a case, the portion of the conductive part at the first base body 11 side can be considered to be the first bonding electrode 31; and the portion of the conductive part at the second base body 12 side can be considered to be the second bonding electrode 32.

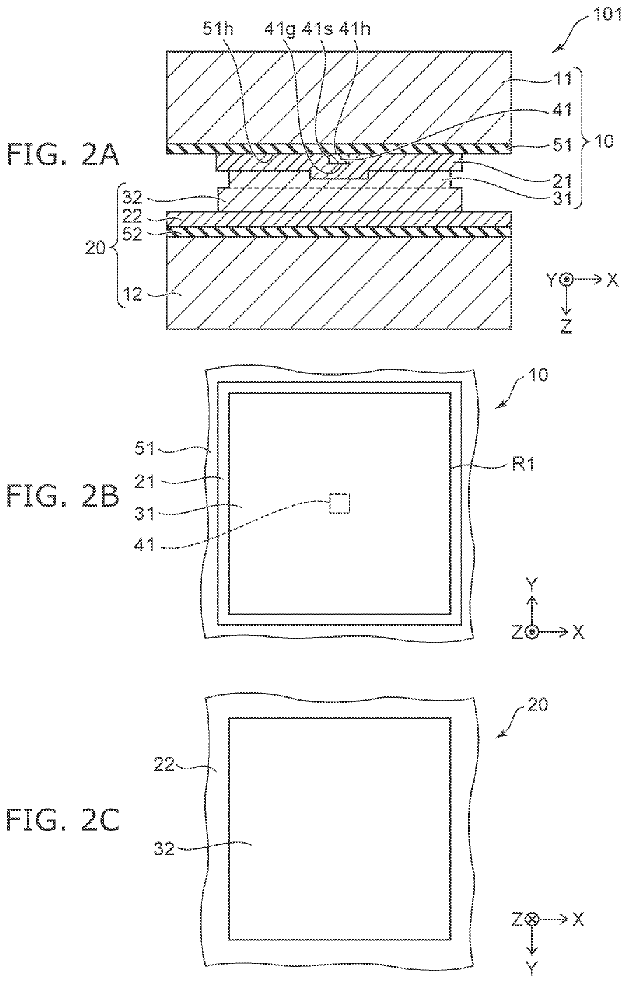

FIGS. 2A to 2C are schematic views illustrating another electronic device according to the embodiment.

FIG. 2A is a schematic cross-sectional view illustrating the electronic device 101 according to the embodiment. FIG. 2B is a schematic plan view illustrating the first structure body 10. FIG. 2C is a schematic plan view illustrating the second structure body 20.

In the electronic device 101, the first hard part 41 is located between the first wiring part 21 and the first base body 11. Otherwise, a description similar to that of the electronic device 100 is applicable to the electronic device 101.

As illustrated in FIGS. 2A and 2B, the surface 41h of the first hard part 41 at the first base body 11 side contacts a surface 51h of the first insulating film 51 at the second base body 12 side. The first hard part 41 is covered with the first wiring part 21 and is enclosed with the first wiring part 21. The four side surfaces 41s of the first hard part 41 and the surface 41g of the first hard part 41 at the second base body 12 side contact the first wiring part 21. In such a case, basically, the surface 41g contacts the first bonding electrode 31 via the first wiring part 21; however, the surface 41g and the first bonding electrode 31 may contact each other if, for example, the height of the first hard part 41 is greater than the height of the first wiring part 21.

In the electronic device 101 as well, similarly to the electronic device 100, the occurrence of defects of the bonding between the first bonding electrode 31 and the second bonding electrode 32 can be suppressed. The yield of the electronic device can be increased thereby.

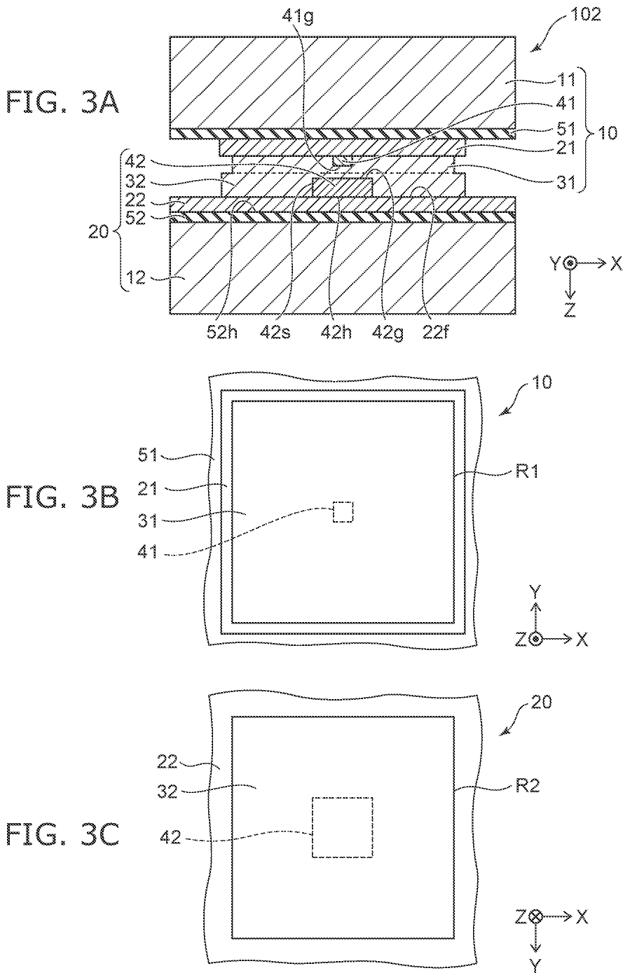

FIGS. 3A to 3C are schematic views illustrating another electronic device according to the embodiment.

FIG. 3A is a schematic cross-sectional view illustrating the electronic device 102 according to the embodiment. FIG. 3B is a schematic plan view illustrating the first structure body 10. FIG. 3C is a schematic plan view illustrating the second structure body 20.

In the electronic device 102, the second structure body 20 includes a second hard part 42. Otherwise, a description similar to that of the electronic device 100 is applicable to the electronic device 102.

The second hard part 42 is located between the first base body 11 (or the first bonding electrode 31) and the second base body 12. In the example, the second hard part 42 is located between the second base body 12 and the second bonding electrode 32 (more specifically, between the second wiring part 22 and the second bonding electrode 32). For example, a surface 42h of the second hard part 42 at the second base body 12 side contacts a surface 22f of the second wiring part 22 at the first base body 11 side.

As illustrated in FIG. 3C, the second hard part 42 is positioned within an area R2 in which the second bonding electrode 32 is located in a plane perpendicular to the Z-direction. For example, none of the second hard part 42 is located outside the area R2 when viewed along the Z-direction. The entire second hard part 42 overlaps the first and second bonding electrodes 31 and 32. The area R2 is surrounded with the outer perimeter of one bonding electrode 32 when viewed along the Z-direction. In the example, the area R2 is a rectangular region. The shape of the second hard part 42 is not limited to rectangular and may be circular, polygonal, etc.

In the example illustrated in FIGS. 3A and 3C, the second hard part 42 is positioned at the central part of the area R2, is covered with the second bonding electrode 32, and is enclosed with the second bonding electrode 32. For example, four side surfaces 42s of the second hard part 42 and a surface 42g of the second hard part 42 at the first base body 11 side contact the second bonding electrode 32. However, the arrangement of the second hard part 42 is not limited thereto; for example, the second hard part 42 may be located at an end portion of the area R2. The surface 42g may contact the first bonding electrode 31.

In the example, at least a portion of the first hard part 41 overlaps at least a portion of the second hard part 42 in the Z-direction. The surface 42g of the second hard part 42 may contact the surface 41g of the first hard part 41.

As illustrated in FIG. 3C, the planar shape of the second hard part 42 is rectangular. However, the planar shape of the second hard part 42 is not limited thereto and is arbitrary. Multiple second hard parts 42 may be located within one area R2. In the example of FIG. 3A, the surface 42g is a plane extending along the X-Y plane. However, the shape of the second hard part 42 is not limited thereto and is arbitrary. For example, the second hard part 42 may include a curved surface or may be conical or frustum-shaped.

The hardness (or rigidity) of the second hard part 42 is greater than the hardness (or rigidity) of the second bonding electrode 32. That is, the second hard part 42 includes a material having a higher hardness than the material of the second bonding electrode 32. The material of the second hard part 42 can include a material similar to the description of the first hard part 41. The material of the second hard part 42 may be the same as or different from the material of the first hard part 41.

The hardness (or rigidity) of the second hard part 42 may be greater than the hardness (or rigidity) of the first bonding electrode 31. That is, the second hard part 42 may include a material having a higher hardness than the material of the first bonding electrode 31.

By including the second hard part 42, similarly to the electronic device described above, for example, the adhesion between the first bonding electrode 31 and the second bonding electrode is more easily improved. For example, the occurrence of open defects between the first bonding electrode 31 and the second bonding electrode 32 can be further suppressed.

Or, the distance between the first base body 11 and the second base body 12 can be regulated by the first and second hard parts 41 and 42. For example, the deformation of the first bonding electrode 31 and the second bonding electrode 32 can be suppressed thereby, and the occurrence of short defects can be further suppressed.

As described above, at least a portion of the first hard part 41 overlaps at least a portion of the second hard part 42 in the Z-direction. In such a case, the adhesion between the first bonding electrode 31 and the second bonding electrode 32 between the first hard part 41 and the second hard part 42 is more easily improved. Or, when the first hard part 41 and the second hard part 42 are in contact, the first hard part 41 and the second hard part 42 function as, for example, stoppers. The occurrence of bonding defects can be further suppressed.

As illustrated in FIG. 3A, the X-direction length of the second hard part 42 may be greater than the X-direction length of the first hard part 41. For example, the effects of misalignment between the first hard part 41 and the second hard part 42 when bonding can be suppressed thereby. Similarly, the Y-direction length of the second hard part 42 may be greater than the Y-direction length of the first hard part 41.

The second hard part 42 may be located between the second wiring part 22 and the second base body 12. The surface 42h of the second hard part 42 at the second base body 12 side may contact a surface 52h of the second insulating film 52 at the first base body 11 side. The second hard part 42 may be covered with the second wiring part 22 and enclosed with the second wiring part 22. The four side surfaces 42s of the second hard part 42 and the surface 42g of the second hard part 42 at the first base body 11 side may contact the second wiring part 22. In such a case, basically, the surface 42g contacts the second bonding electrode 32 via the second wiring part 22; however, the surface 42g and the second bonding electrode 32 may contact each other when, for example, the height of the second hard part 42 is greater than the height of the second wiring part 22.

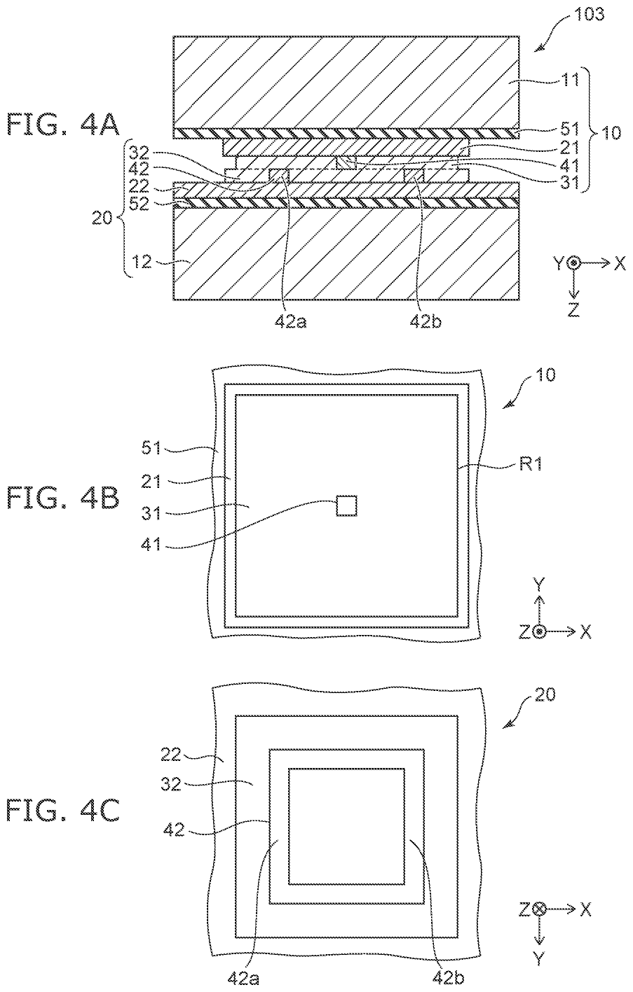

FIGS. 4A to 4C are schematic views illustrating another electronic device according to the embodiment. FIG. 4A is a schematic cross-sectional view illustrating the electronic device 103 according to the embodiment. FIG. 4B is a schematic plan view illustrating the first structure body 10. FIG. 4C is a schematic plan view illustrating the second structure body 20.

The shapes of the first and second hard parts 41 and 42 of the electronic device 103 are different from those of the electronic device 102. Otherwise, a description similar to that of the electronic device 102 is applicable to the structure of the electronic device 103.

In the example, the first hard part 41 does not overlap the second hard part 42 in the Z-direction. For example, at least a portion of the first hard part 41 is positioned between a portion 42a of the second hard part 42 and another portion 42b of the second hard part 42 in a plane perpendicular to the Z-direction (when viewed along the Z-direction).

More specifically, the first hard part 41 is surrounded with the second hard part 42 when viewed along the Z-direction. As illustrated in FIG. 4B, the first hard part 41 is positioned at the center of the first bonding electrode 31 when viewed along the Z-direction. As illustrated in FIG. 4C, the second hard part 42 has a rectangular opening at the center when viewed along the Z-direction. The outer perimeter and the inner perimeter of the second hard part 42 are rectangular. The first hard part 41 is positioned inward of the inner perimeter of the second hard part 42 when viewed along the Z-direction.

For example, such positions and shapes of the first and second hard parts 41 and 42 cause the movement in the X-Y plane of the first hard part 41 to be regulated by the second hard part 42. For example, misalignment along the X-Y plane of the position of the first structure body 10 with respect to the second structure body 20 in a bonding process described below can be suppressed. The shape of the first hard part 41 and the shape of the opening of the second hard part 42 are not limited to rectangular and may be circular or polygonal.

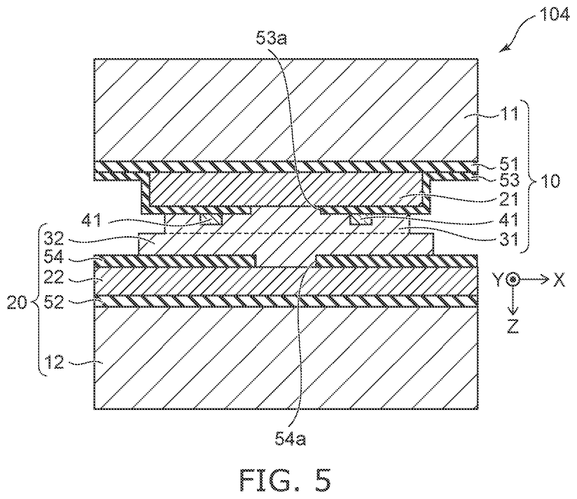

FIG. 5 is a schematic cross-sectional view illustrating another electronic device according to the embodiment.

In the electronic device 104 illustrated in FIG. 5, the first structure body 10 further includes an insulating film 53. The second structure body 20 further includes an insulating film 54. The position and shape of the first hard part 41 of the electronic device 104 are different from those of the electronic device 100. Otherwise, a description similar to that of the electronic device 100 is applicable to the structure of the electronic device 104.

The insulating film 53 is located between the first wiring part 21 and the first bonding electrode 31. The insulating film 53 contacts the first wiring part 21 and the first bonding electrode 31. The first bonding electrode 31 contacts the first wiring part 21 in an opening 53a provided in the insulating film 53.

The first hard part 41 is located between the insulating film 53 and the second base body 12. In the example, two first hard parts 41 are located between the insulating film 53 and the first bonding electrode 31. The X-direction position of the opening 53a of the insulating film 53 is between the X-direction position of one first hard part 41 and the X-direction position of the other first hard part 41. Or, the first hard part 41 may be rectangular with an opening at the center. In such a case, the opening 53a of the insulating film 53 is positioned inward of the inner perimeter of the first hard part 41 when viewed along the Z-direction.

The insulating film 54 is located between the second wiring part 22 and the second bonding electrode 32. The insulating film 54 contacts the second wiring part 22 and the second bonding electrode 32. The second bonding electrode 32 contacts the second wiring part 22 in an opening 54a provided in the insulating film 54. The insulating film 53 and the insulating film 54 include, for example, at least one of silicon oxide, silicon nitride, or polyimide.

In the electronic device 104 as well, similarly to the electronic device 100, the occurrence of defects of the bonding between the first bonding electrode 31 and the second bonding electrode 32 can be suppressed. The yield of the electronic device can be increased thereby. The opening 53a and the opening 54a may not be at the centers of the bonding electrodes and may be, for example, offset to one side.

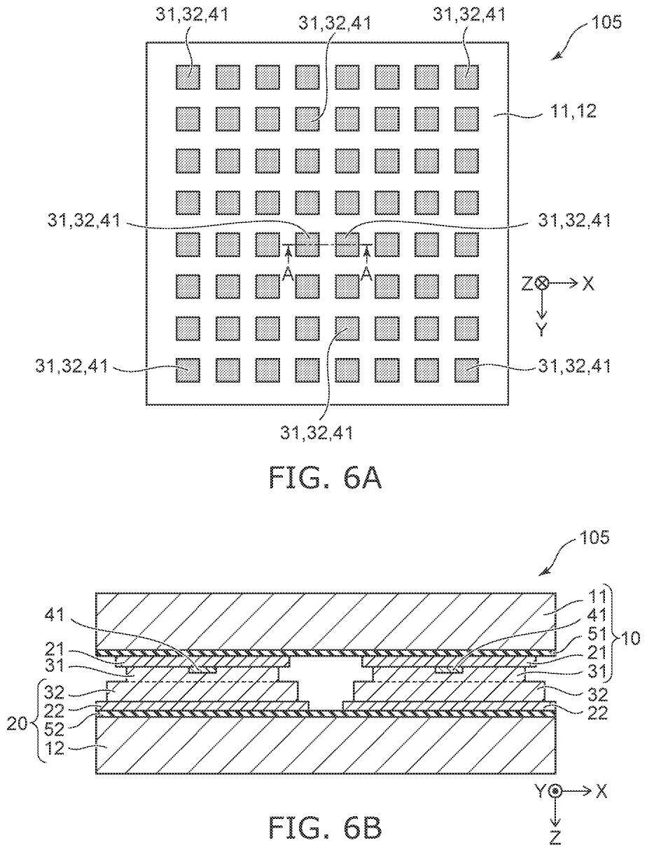

FIGS. 6A and 6B are schematic views illustrating another electronic device according to the embodiment. FIG. 6A is a schematic plan view illustrating the electronic device 105 according to the embodiment. Some of the components are not illustrated to simplify the display for easier viewing in FIG. 6A. FIG. 6B is a schematic cross-sectional view illustrating a line A-A cross section shown in FIG. 6A.

In the electronic device 105, the first structure body 10 and the second structure body 20 each are semiconductor substrates (chips). As illustrated in FIG. 6A, the planar shapes of the first and second structure bodies 10 and 20 each are rectangular. The multiple components that are included in the first and second structure bodies 10 and 20 may not all have the same size and shape. The first structure body 10 and the second structure body 20 may not have the same size and shape.

In the electronic device 105, the first structure body 10 includes the multiple first bonding electrodes 31 and the multiple first hard parts 41. For example, the multiple first bonding electrodes 31 are arranged in the X-direction and the Y-direction. In other words, the multiple first bonding electrodes 31 are arranged in an array configuration in the X-Y plane.

The second structure body 20 includes the multiple second bonding electrodes 32. For example, the multiple second bonding electrodes 32 are arranged in the X-direction and the Y-direction. The multiple second bonding electrodes 32 are arranged to correspond respectively to the multiple first bonding electrodes 31. In other words, the multiple second bonding electrodes 32 are arranged to be connected respectively with the multiple first bonding electrodes 31. Specifically, the multiple second bonding electrodes 32 respectively overlap the multiple first bonding electrodes 31 when viewed along the Z-direction. That is, one second bonding electrode 32 overlaps one bonding electrode 31 when viewed along the Z-direction.

The multiple first hard parts 41 are provided to correspond to the multiple first bonding electrodes 31. The multiple first hard parts 41 respectively overlap the multiple first bonding electrodes 31 when viewed along the Z-direction. That is, one first hard part 41 overlaps one bonding electrode 31 when viewed along the Z-direction. For example, all of the first bonding electrodes 31 overlap at least one first hard part 41 each when viewed along the Z-direction.

According to the electronic device 105, even when multiple bonding electrodes are included, bonding defects of the bonding electrodes can be suppressed similarly to the description of the electronic device described above. The yield of the electronic device can be further improved thereby. The shapes and arrangement of the electrodes are not necessarily uniform. It is unnecessary for the electrodes to be aligned. Also, it is unnecessary for all of the hard parts to have the same shape. The arrangement of the hard parts can be changed according to the arrangement of the electrodes.

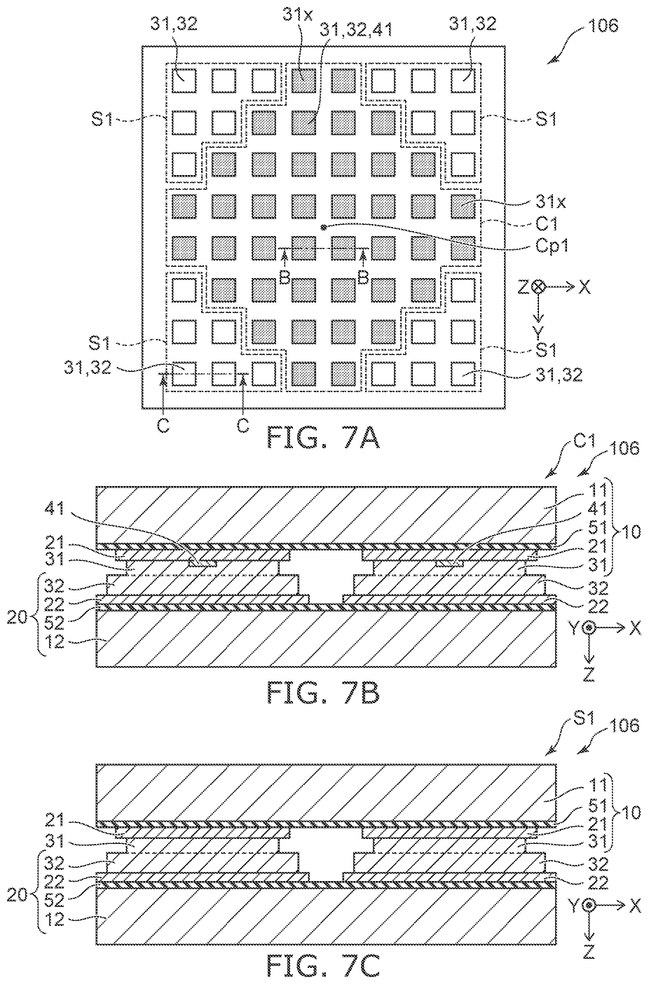

FIGS. 7A to 7C are schematic views illustrating another electronic device according to the embodiment. FIG. 7A is a schematic plan view illustrating the electronic device 106 according to the embodiment. Some of the components are not illustrated to simplify the illustration for easier viewing in FIG. 7A. FIG. 7B is a schematic cross-sectional view illustrating a line B-B cross section shown in FIG. 7A. FIG. 7C is a schematic cross-sectional view illustrating a line C-C cross section shown in FIG. 7A.

The arrangement of the first hard part 41 of the electronic device 106 is different from that of the electronic device 105. Otherwise, a description similar to that of the electronic device 105 is applicable to the configuration of the electronic device 106.

As illustrated in FIG. 7A, the first base body 11 (the first structure body 10) includes a central region C1 and an outer region S1 positioned outward of the central region C1 in a plane perpendicular to the Z-direction. In other words, at least a portion of the central region C1 is positioned between at least a portion of the outer region S1 and a center point Cp1 of the first base body 11 when viewed along the Z-direction. When viewed from the center point Cp1, the outer region S1 is located outward of at least a portion of the central region C1 when viewed in plan as in FIG. 7A.

Multiple first bonding electrodes 31 are located in the central region C1; and multiple first bonding electrodes 31 are located in the outer region S1. In other words, a portion of the multiple first bonding electrodes 31 is located in the central region C1; and another portion of the multiple first bonding electrodes 31 is located in the outer region S1. In the example, the outer region S1 includes four corner portions of the region in which the first bonding electrodes 31 are arranged in an array configuration. The central region C1 may be a portion of a region such that the first bonding electrodes 31 are arranged in the array configuration that includes the first bonding electrode 31 at the outermost perimeter (e.g., a first bonding electrode 31x shown in FIG. 7A).

FIG. 7B illustrates the cross section of the central region C1; and FIG. 7C illustrates the cross section of the outer region S1. Multiple first hard parts 41 are located in the central region C1, but the first hard part 41 is not located in the outer region S1. The multiple first hard parts 41 respectively overlap the multiple first bonding electrodes 31 located in the central region C1 when viewed along the Z-direction, that is, one first hard part 41 overlaps one bonding electrode 31 located in the central region C1 when viewed along the Z-direction.

There are cases where bonding defects (e.g., open defects) between the bonding electrodes occur more easily in the central region of the chip than in the outer region of the chip. For example, compared to the outer region, there are cases where the bonding adhesion between the bonding electrodes is poor in the central region of the chip. In contrast, according to the embodiment, the first hard part 41 is located in the central region C1. Similarly to the description of the electronic device described above, for example, bonding defects in the central region C1 can be suppressed thereby, and the yield of the electronic device can be increased. The shape and arrangement of the electrodes are not necessarily uniform. Also, it is unnecessary for the electrodes to be aligned. It is unnecessary for all of the hard parts to have the same shape. The arrangement of the hard parts can be different according to the arrangement of the electrodes.

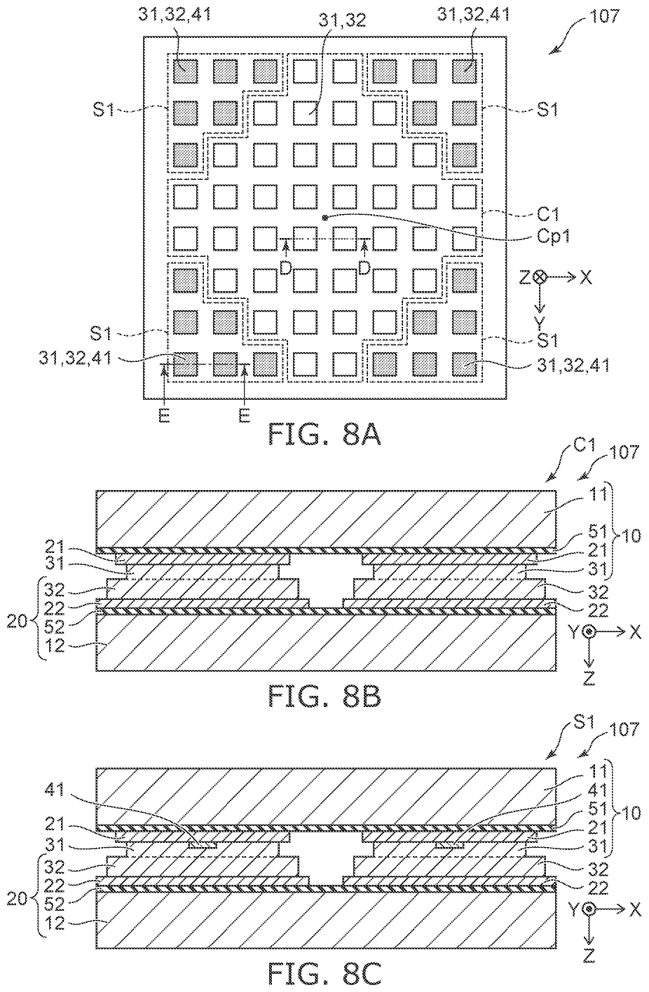

FIGS. 8A to 8C are schematic views illustrating another electronic device according to the embodiment. FIG. 8A is a schematic plan view illustrating the electronic device 107 according to the embodiment. Some of the components are not illustrated to simplify the illustration for easier viewing in FIG. 8A. FIG. 8B is a schematic cross-sectional view illustrating a line D-D cross section shown in FIG. 8A. FIG. 8C is a schematic cross-sectional view illustrating a line E-E cross section shown in FIG. 8A.

The arrangement of the first hard part 41 of the electronic device 107 is different from that of the electronic device 106. Otherwise, a description similar to that of the electronic device 106 is applicable to the configuration of the electronic device 107.

FIG. 8B illustrates a cross section of the central region C1; and FIG. 8C illustrates a cross section of the outer region S1. Multiple first hard parts 41 are located in the outer region S1, but the first hard part 41 is not located in the central region C1. The multiple first hard parts 41 respectively overlap the multiple first bonding electrodes 31 located in the outer region S1 when viewed along the Z-direction, that is, one first hard part 41 overlaps one bonding electrode 31 located in the outer region S1 when viewed along the Z-direction.

Compared to the central region of the chip, there are cases where bonding defects (e.g., short defects) between the bonding electrodes occur more easily in the outer region of the chip. For example, compared to the central region, there are cases where deformation of the bonding electrodes when bonding occurs more easily in the outer region of the chip. In contrast, according to the embodiment, the first hard part 41 is located in the outer region S1. For example, similarly to the description of the electronic device described above, the bonding defects in the outer region S1 can be suppressed thereby, and the yield of the electronic device can be increased. The shape and arrangement of the electrodes are not necessarily uniform. Also, it is unnecessary for the electrodes to be aligned. It is unnecessary for all of the hard parts to have the same shape. The arrangement of the hard parts can be different according to the arrangement of the electrodes.

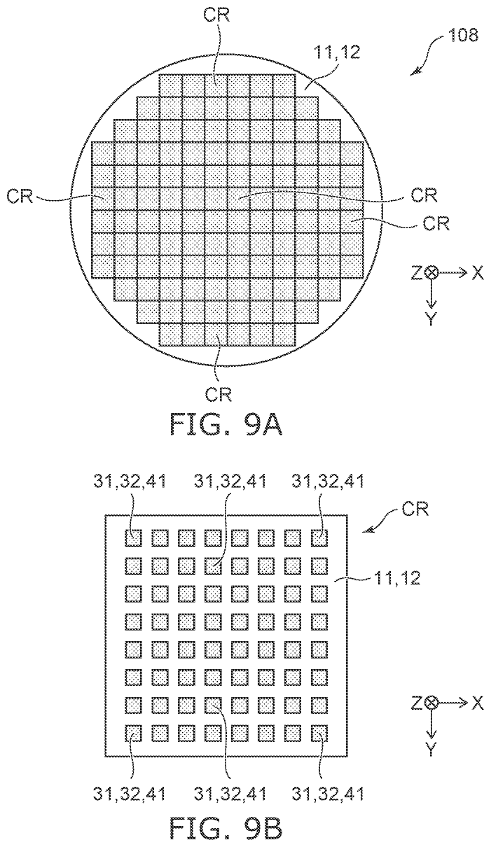

FIGS. 9A and 9B are schematic views illustrating another electronic device according to the embodiment. FIG. 9A is a schematic plan view illustrating the electronic device 108 according to the embodiment. FIG. 9B is a partially enlarged view of FIG. 9A. Some of the components are not illustrated to simplify the illustration for easier viewing in FIGS. 9A and 9B.

In the electronic device 108, the first structure body 10 and the second structure body 20 each are semiconductor substrates (wafers). The first structure body 10 and the second structure body 20 include multiple chip regions CR. The multiple chip regions CR are arranged in the X-direction and the Y-direction.

FIG. 9B illustrates the multiple chip regions CR. A description similar to the electronic device 105 described with reference to FIGS. 6A and 6B is applicable to the configuration of each chip region CR of the example. For example, the first hard part 41 is included in all of the chip regions CR. In other words, the multiple bonding electrodes 31 overlap the multiple first hard parts 41 when viewed along the Z-direction in all of the chip regions CR.

Thus, each structure body (each base body) may be a wafer. In such a case as well, bonding defects of the bonding electrodes can be suppressed similarly to the description of the electronic device described above. The yield of the electronic device can be increased thereby.

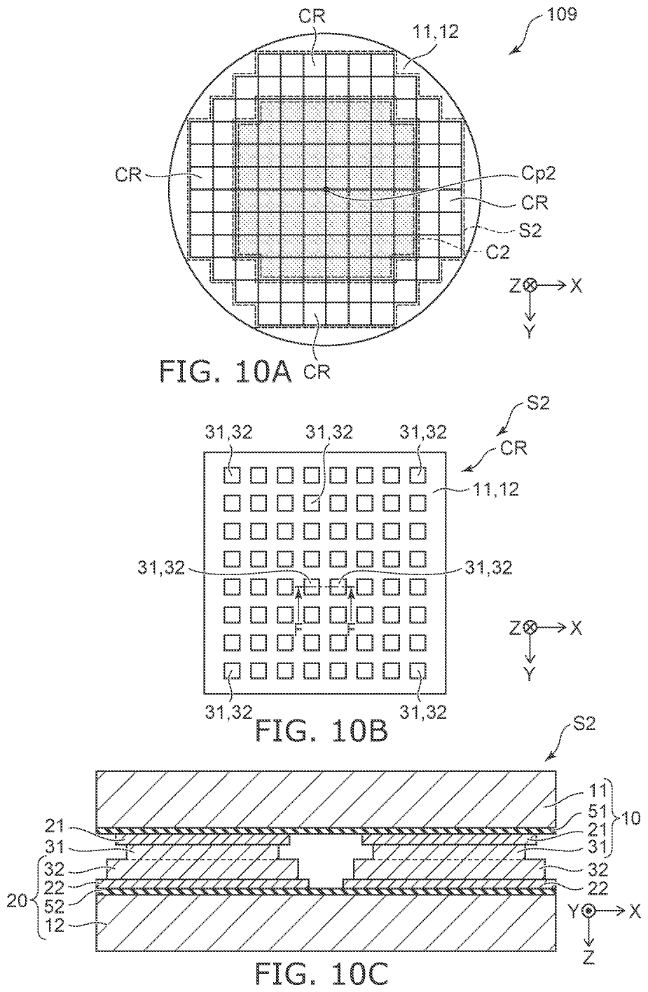

FIGS. 10A to 10C are schematic views illustrating another electronic device according to the embodiment. FIG. 10A is a schematic plan view illustrating the electronic device 109 according to the embodiment. FIG. 1013 is a partially enlarged view of FIG. 10A. Some of the components are not illustrated to simplify the illustration for easier viewing in FIGS. 10A and 1013. FIG. 10C is a schematic cross-sectional view illustrating a line F-F cross section shown in FIG. 10B.

The arrangement of the first hard part 41 of the electronic device 109 is different from that of the electronic device 108. Otherwise, a description similar to that of the electronic device 108 is applicable to the configuration of the electronic device 109.

As illustrated in FIG. 10A, the first base body 11 (the first structure body 10) includes a central region C2 and an outer region S2 positioned outward of the central region C2 in a plane perpendicular to the Z-direction. In other words, at least a portion of the central region C2 is positioned between at least a portion of the outer region S2 and a center point Cp2 of the first base body 11 when viewed along the Z-direction. When viewed from the center point Cp2, the outer region S2 is located outward of at least a portion of the central region C2 when viewed in plan as in FIG. 10A.

Multiple chip regions CR are located in the central region C2; and multiple chip regions CR are located in the outer region S2. In other words, a portion of the multiple chip regions CR is located in the central region C2; and another portion of the multiple chip regions is located in the outer region S2. A description similar to the chip region CR described with reference to FIG. 9B is applicable to the configuration of the chip region CR located in the central region C2. In other words, for example, the first hard part 41 is located in all of the chip regions CR of the central region C2.

FIGS. 10B and 10C illustrate the chip region CR located in the outer region S2. In the chip region CR of the outer region S2 as illustrated in FIGS. 10B and 10C, the first structure body 10 includes the first base body 11, the first wiring part 21, the first bonding electrode 31, and the first insulating film 51; and the second structure body 20 includes the second base body 12, the second wiring part 22, the second bonding electrode 32, and the second insulating film 52. In the example, the multiple first hard parts 41 are not included in the outer region S2.

Compared to the outer region of the wafer, there are cases where bonding defects (e.g., open defects) between the bonding electrodes occur easily in the central region of the wafer. For example, compared to the outer region, there are cases where the adhesion between the bonding electrodes when bonding is poor in the central region of the wafer. In contrast, according to the embodiment, the first hard part 41 is located in the central region C2. For example, similarly to the description of the electronic device described above, the bonding defects in the central region C2 can be suppressed thereby, and the yield of the electronic device can be increased.

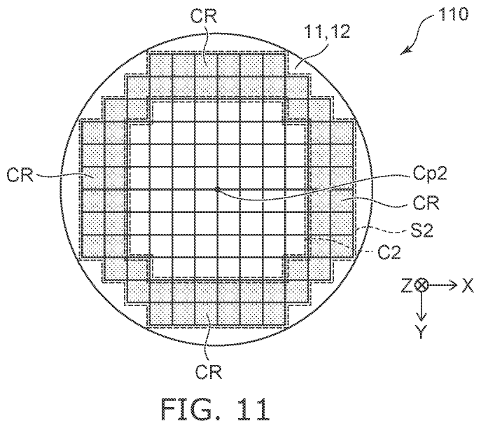

FIG. 11 is a schematic plan view illustrating another electronic device according to the embodiment.

In FIG. 11, some of the components are not illustrated to simplify the illustration for easier viewing. The arrangement of the first hard part 41 of the electronic device 110 illustrated in FIG. 11 is different from that of the electronic device 109. Otherwise, a description similar to the electronic device 108 is applicable to the configuration of the electronic device 110.

A description similar to the chip region CR described with reference to FIGS. 1013 and 10C is applicable to the configuration of the chip region CR located in the central region C2 of the electronic device 110. In other words, in the example, the multiple first hard parts 41 are not located in the central region C2.

A description similar to the chip region CR described with reference to FIG. 9B is applicable to the configuration of the chip region CR located in the outer region S2 of the electronic device 110. In other words, for example, the first hard part 41 is located in all of the chip regions CR of the outer region S2.

Compared to the central region of the wafer, there are cases where bonding defects (e.g., short defects) between the bonding electrodes occur more easily in the outer region of the wafer. For example, compared to the central region, there are cases where deformation of the bonding electrodes when bonding occurs more easily in the outer region of the wafer. In contrast, according to the embodiment, the first hard part 41 is located in the outer region S2. For example, similarly to the description of the electronic device described above, bonding defects in the outer region S2 can be suppressed thereby, and the yield of the electronic device can be increased.

A method for manufacturing the electronic device according to the embodiment described above will now be described.

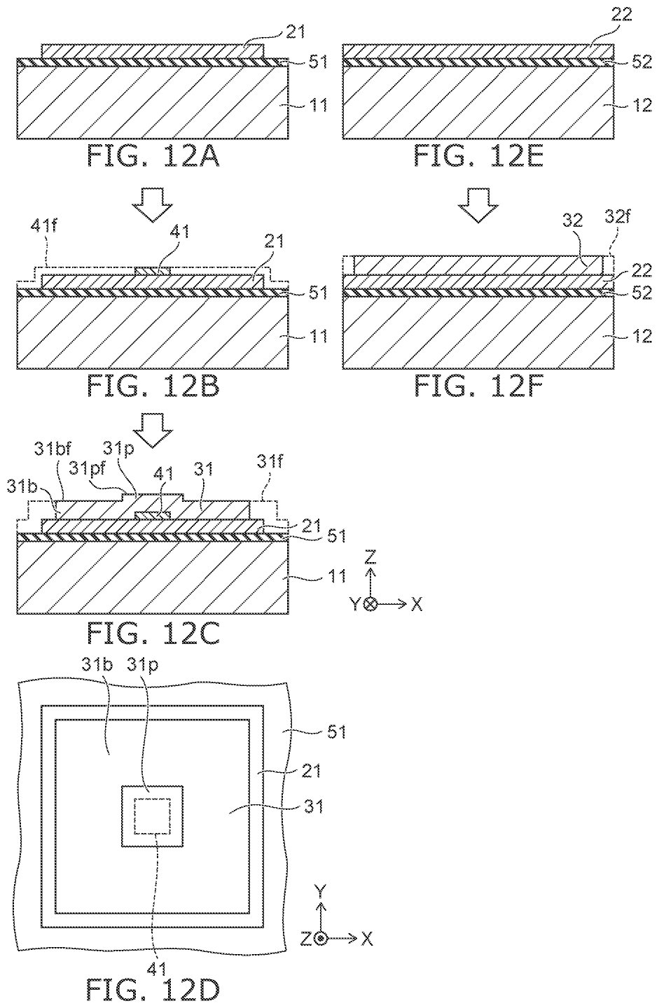

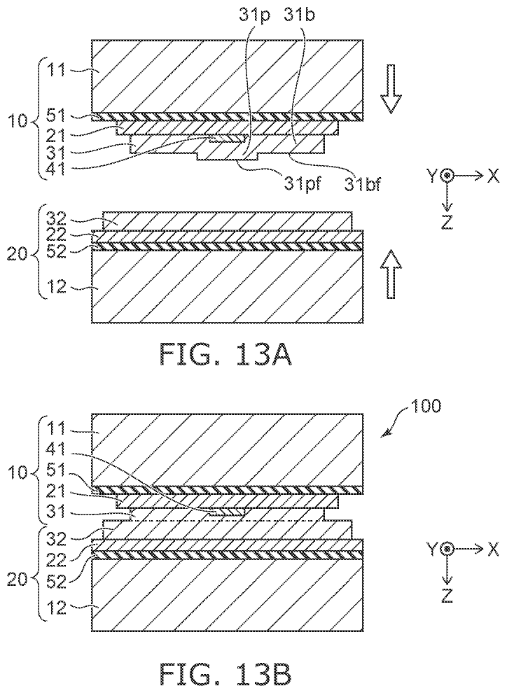

FIGS. 12A to 12F, FIG. 13A, and FIG. 13B are schematic views illustrating the method for manufacturing the electronic device according to the embodiment.

These drawings illustrate the method for manufacturing the electronic device 100 described with reference to FIGS. 1A to 1C. FIGS. 12A to 12C are schematic cross-sectional views in order of the processes, illustrating a portion of the manufacturing processes of the first structure body 10. FIG. 12D is a schematic plan view illustrating the first structure body 10 illustrated in FIG. 12C. FIGS. 12E and 12F are schematic cross-sectional views in order of the processes, illustrating a portion of the manufacturing processes of the second structure body 20.

As illustrated in FIG. 12A, the first wiring part 21 (and the first element part) are formed at the first base body 11 (a wiring layer formation process). A portion of the first wiring part 21 is located on the first base body 11.

As illustrated in FIG. 12B, the first hard part 41 is formed on the first wiring part 21 (a hard part formation process). In the hard part formation process, a first hard layer 41f is formed on at least a portion of the first base body 11 and the first wiring part 21; and the first hard part 41 is formed by patterning the first hard layer 41f.

In the description of the embodiments, the formation of a layer on a component may include not only the formation of the layer directly on the component, but also the formation of the layer indirectly on the component. In other words, the formation of a layer on a component may include not only the case where the layer contacts the component but also the case where another layer is formed between the layer and the component.

In the example, the first hard layer 41f is formed directly on the first wiring part 21 and the first insulating film 51. In other words, the first hard layer 41f contacts the first wiring part 21 and the first insulating film 51. The first hard layer 41f is, for example, a silicon oxide film. Subsequently, for example, the first hard layer 41f is patterned by photolithography and etching (e.g., reactive ion etching (Reactive Ion Etching)). In the patterning, for example, a resist film is formed on the object layer; and a portion of the resist film is caused to remain by photolithography. The resist film is stripped away after the object layer is patterned by etching using the remaining resist film as a mask. By the patterning, a portion of the first hard layer 41f positioned on a portion of the first wiring part 21 remains, and the rest is removed. The first hard part 41 is formed thereby.

As illustrated in FIG. 12C, a metal layer 31f is formed on the first wiring part 21 and the first hard part 41; and the first bonding electrode 31 is formed by patterning the metal layer 31f (an electrode formation process).

In the example, the metal layer 31f is formed directly on the first wiring part 21 and the first hard part 41. In other words, the metal layer 31f contacts the first wiring part 21 and the first hard part 41. Subsequently, for example, the metal layer 31f is patterned by photolithography and etching (e.g., reactive ion etching). The patterning causes a portion of the metal layer 31f positioned on a portion of the first wiring part 21 and a portion of the metal layer 31f positioned on the first hard part 41 to remain, and removes the rest. The first bonding electrode 31 is formed thereby.

The first bonding electrode 31 may include multiple layers. For example, the first bonding electrode 31 includes a Ti/Pd layer (a barrier metal layer) and a Au layer. In such a case, for example, a Ti/Pd layer (layers in which the Ti layer is stacked on the Pd layer) is formed and patterned on the first wiring part 21 and the first hard part 41. A Au layer is formed on the Ti/Pd layer; and the resist is stripped away. The first bonding electrode 31 may be formed thereby.

As illustrated in FIGS. 12C and 12D, the first bonding electrode 31 includes a first electrode part 31b and a first protruding part 31p before the bonding process described below. The first protruding part 31p protrudes in the Z-direction from the first electrode part 31b. For example, the first protruding part 31p protrudes according to the first hard part 41. The first hard part 41 is positioned between the first protruding part 31p and the first base body 11. As illustrated in FIG. 12D, the planar shape of the first protruding part 31p corresponds to the planar shape of the first hard part 41 and is rectangular in the example.

For example, the first bonding electrode 31 has a staircase shape before the bonding process. In other words, as illustrated in FIG. 12C, the first electrode part 31b includes a first electrode surface 31bf; and the first protruding part 31p includes a first end surface 31pf having a different height from the first electrode surface 31bf. The first end surface 31pf is the Z-direction tip surface of the first protruding part 31p and protrudes in the Z-direction from the first electrode surface 31bf. The first electrode surface 31bf and the first end surface 31pf each extend along the X-Y plane. The height of the first hard part 41 may be higher than the upper surface of the first bonding electrode 31.

According to the embodiment, the first bonding electrode 31 may not always have a staircase shape. For example, the first bonding electrode 31 may be conical or frustum-shaped. For example, the tip surface of the first protruding part 31p may include not only straight lines but also may include curves and corners when viewed in cross-section as in FIG. 12C.

As illustrated in FIG. 12E, the second wiring part 22 (and the second element part) are formed at the second base body 12 (a wiring layer formation process). A portion of the second wiring part 22 is located on the second base body 12.

As illustrated in FIG. 12F, a metal layer 32f is formed on the second wiring part 22; and the second bonding electrode 32 is formed by patterning the metal layer 32f (an electrode formation process).

FIGS. 13A and 13B are schematic cross-sectional views in order of the processes, illustrating bonding between the first structure body 10 and the second structure body 20. As shown in FIGS. 13A and 13B, the first bonding electrode 31 and the second bonding electrode 32 are bonded (a bonding process). The first structure body 10 and the second structure body 20 are bonded thereby.

Specifically, the first structure body 10 of FIG. 12C and the second structure body 20 of FIG. 12F are arranged as illustrated in FIG. 13A. In other words, the first bonding electrode 31 and the second bonding electrode 32 are caused to face each other between the first base body 11 and the second base body 12; and the first structure body 10 and the second structure body 20 are overlaid. Then, the first bonding electrode 31 and the second bonding electrode 32 are brought into contact and compression-bonded. In other words, pressure toward the second structure body 20 is applied to the first structure body 10; and pressure toward the first structure body 10 is applied to the second structure body 20. Thereby, the first bonding electrode 31 and the second bonding electrode 32 are pressed toward each other in the Z-direction; and the first bonding electrode 31 and the second bonding electrode 32 are compression-bonded.

In such a bonding process, first, the first protruding part 31p (the first end surface 31pf) and the second bonding electrode 32 are brought into contact and pressurized. As the pressure is applied, the first protruding part 31p is mashed and compression-bonded as illustrated in FIG. 13B. Then, the first electrode part 31b (the first electrode surface 31bf) and the second bonding electrode 32 contact and are compression-bonded. Thus, the electronic device 100 can be manufactured. In this process, heat can be applied simultaneously with pressure to increase the compression bonding effect.

Thus, the bonding process includes causing the first protruding part 31p and the second bonding electrode 32 to contact each other in the Z-direction. Here, because the first bonding electrode 31 includes the first protruding part 31p, the contact area between the bonding electrodes can be reduced at the start of the bonding process. In other words, compared to the contact area between the bonding electrodes (e.g., the surface area of the first bonding electrode) when the bonding electrode does not include a protruding part, the contact area between the first protruding part 31p and the second bonding electrode 32 (e.g., the surface area of the first end surface 31pf) is small. By reducing the contact area, the pressure per unit area can be increased. For example, the first bonding electrode 31 and the second bonding electrode 32 can be easily bonded thereby, and the occurrence of the bonding defects (e.g., the open defects) between the bonding electrodes can be suppressed. Accordingly, the yield of the electronic device can be increased.

As described above, the first hard part 41 is included in the first structure body 10. The first protruding part 31p can be formed thereby. For example, as described above, the hard part formation process includes forming the first hard part 41 by patterning the first hard layer 41f. The first hard part 41 and the first protruding part 31p can be selectively formed thereby. Also, the position and/or shape of the first protruding part 31p are easily controlled.

In manufacturing methods according to embodiments, for example, a protruding part can be formed in the bonding electrode by a combination of multiple patterning even when the hard part is not included. In such a case as well, the occurrence of bonding defects can be suppressed by reducing the contact area between the bonding electrodes.

The hard part formation process may be performed before forming a portion of the first wiring part 21. For example, the first hard part 41 is formed on the base body 11 or the first insulating film 51. The first hard part 41 described with reference to FIG. 2A is formed thereby. Subsequently, a portion of the first wiring part 21 is formed on the first base body 11 and the first hard part 41; and the first bonding electrode 31 is formed on the portion of the first wiring part 21. Subsequently, similarly to the description above, the electronic device 101 described with reference to FIG. 2A can be manufactured by performing the bonding process.

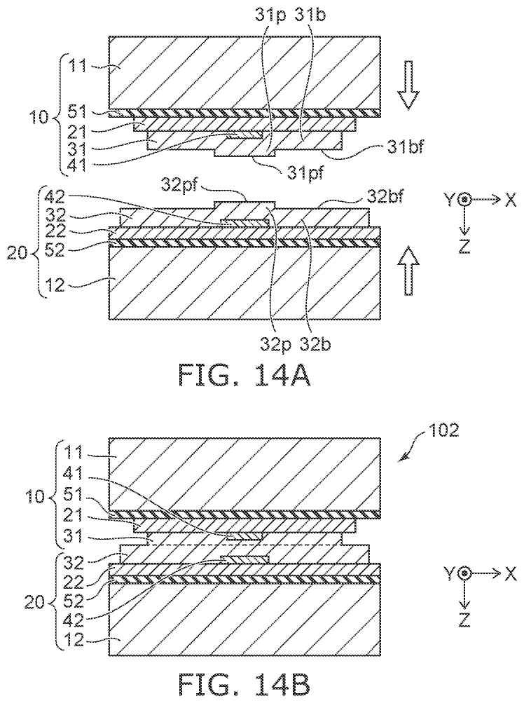

FIGS. 14A and 14B are schematic views illustrating a method for manufacturing another electronic device according to the embodiment.

FIGS. 14A and 14B are schematic cross-sectional views in order of the processes, illustrating bonding between the first structure body 10 and the second structure body 20. These drawings illustrate the method for manufacturing the electronic device 102 described with reference to FIGS. 3A to 3C. As illustrated in FIG. 14A, the first structure body 10 includes the first hard part 41; and the first bonding electrode 31 includes the first electrode part 31b and the first protruding part 31p before the bonding process. The second structure body 20 includes the second hard part 42. The second hard part 42 can be formed when forming the second structure body 20 by adding a similar hard part formation process to that of the first structure body 10. In other words, for example, a hard part formation process of forming the second hard part 42 is added by patterning after the wiring layer formation process of forming the second wiring part 22. Subsequently, an electrode process of forming the second bonding electrode 32 is performed.

As illustrated in FIG. 14A, the second bonding electrode 32 includes a second electrode part 32b and a second protruding part 32p before the bonding process. The second protruding part 32p protrudes in the −Z direction from the second electrode part 32b. For example, the second protruding part 32p protrudes according to the second hard part 42. In other words, the second hard part 42 is positioned between the second protruding part 32p and the second base body 12. The planar shape of the second protruding part 32p corresponds to the planar shape of the second hard part 42 and is rectangular in the example. The −Z direction is the direction from the second base body 12 toward the second bonding electrode 32 and is the opposite direction of the Z-direction in FIG. 14A.

For example, the second bonding electrode 32 has a staircase shape before the bonding process. In other words, as illustrated in FIG. 14A, the second electrode part 32b includes a second electrode surface 32bf; and the second protruding part 32p includes a second end surface 32pf that has a different height from the second electrode surface 32bf. The second end surface 32pf is the −Z direction tip surface of the second protruding part 32p and protrudes in the −Z direction from the second electrode surface 32bf. The second electrode surface 32bf and the second end surface 32pf each extend along the X-Y plane.

According to the embodiment, the second bonding electrode 32 may not always have a staircase shape. For example, the second bonding electrode 32 may be conical or frustum-shaped. For example, the tip surface of the second protruding part 32p may include not only straight lines but also may include curves and corners when viewed in cross-section as in FIG. 14A.

As shown in FIGS. 14A and 14B, the first bonding electrode 31 and the second bonding electrode 32 are bonded (the bonding process). The first structure body 10 and the second structure body 20 are bonded thereby.

In the bonding process first, the first bonding electrode 31 and the second protruding part 32p (the second end surface 32pf) are brought into contact and pressurized. In the example, the first protruding part 31p (the first end surface 31pf) and the second protruding part 32p (the second end surface 32pf) contact each other. As the pressure is applied, the first protruding part 31p and the second protruding part 32p are mashed and compression-bonded as illustrated in FIG. 14B. Then, the first electrode part 31b (the first electrode surface 31bf) and the second electrode part 32b (the second electrode surface 32bf) contact and are compression-bonded. Thus, the electronic device 102 can be manufactured. The first hard part 41 and the second hard part 42 also may contact each other at this time.

In the example as well, the bonding electrodes include protruding parts. For example, the contact area between the bonding electrodes can be reduced thereby, and the first bonding electrode 31 and the second bonding electrode 32 can be easily bonded.

For example, as illustrated in FIG. 14A, the X-direction length of the second protruding part 32p is greater than the X-direction length of the first protruding part 31p before the bonding process. For example, the effects of misalignment between the first bonding electrode 31 and the second bonding electrode 32 when bonding can be suppressed thereby. When the pressure when bonding is large, the first hard part 41 and the second hard part 42 contact each other, and the combined thickness of the first and second bonding electrodes 31 and 32 is prevented from being less than the combined thickness of the first and second hard parts 41 and 42.

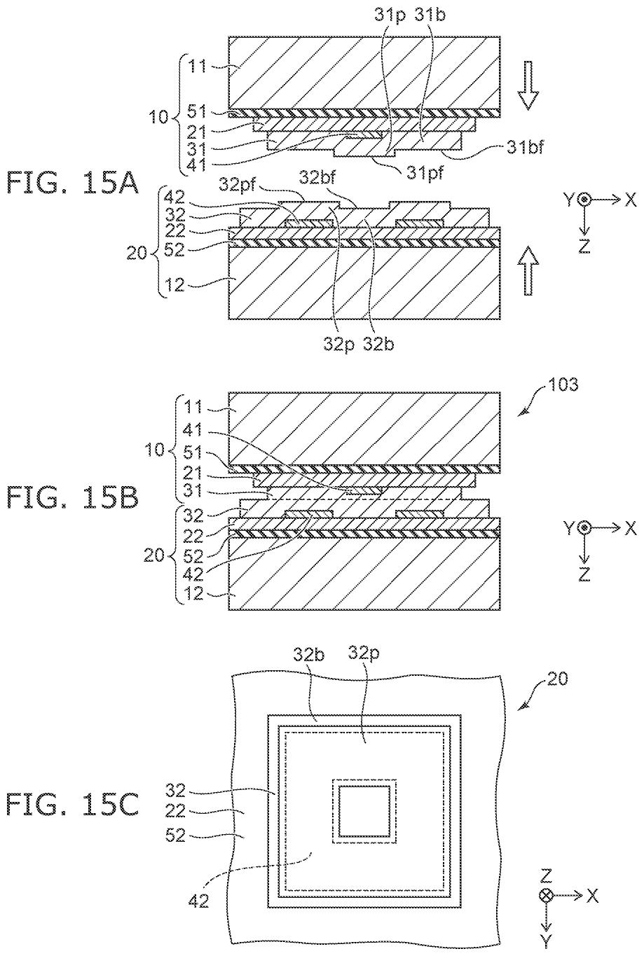

FIGS. 15A to 15C are schematic views illustrating a method for manufacturing another electronic device according to the embodiment.

FIGS. 15A and 15B are schematic cross-sectional views in order of the processes, illustrating bonding between the first structure body 10 and the second structure body 20. FIG. 15C is a schematic plan view illustrating the second structure body 20 before the bonding process. These drawings illustrate the method for manufacturing the electronic device 103 described with reference to FIGS. 4A to 4C. As illustrated in FIG. 15A, the first structure body 10 includes the first hard part 41; and the first bonding electrode 31 includes the first electrode part 31b and the first protruding part 31p before the bonding process. The second structure body 20 includes the second hard part 42; and the second bonding electrode 32 includes the second electrode part 32b and the second protruding part 32p before the bonding process. The positions and shapes of the second hard part 42 and the second protruding part 32p according to the method for manufacturing the electronic device 103 are different from those of the method for manufacturing the electronic device 102 described above.

As illustrated in FIG. 15C, the planar shape of the second protruding part 32p corresponds to the planar shape of the second hard part 42 and includes a rectangular opening (recess) at the center in the example. The outer perimeter and inner perimeter of the second protruding part 32p are rectangular.

In the bonding process, for example, the first protruding part 31p (the first end surface 31pf) and the second electrode part 32b (the second electrode surface 32bf) contact each other, and the second protruding part 32p (the second end surface 32pf) and the first electrode part 31b (the first electrode surface 31bf) contact each other. In other words, the bonding process includes causing the first protruding part 31p and the recess of the second bonding electrode 32 (the second electrode part 32b) to contact in the Z-direction. As the pressure is applied, the first protruding part 31p and the second protruding part 32p are mashed and compression-bonded as illustrated in FIG. 15B. Thus, the electronic device 103 can be manufactured.

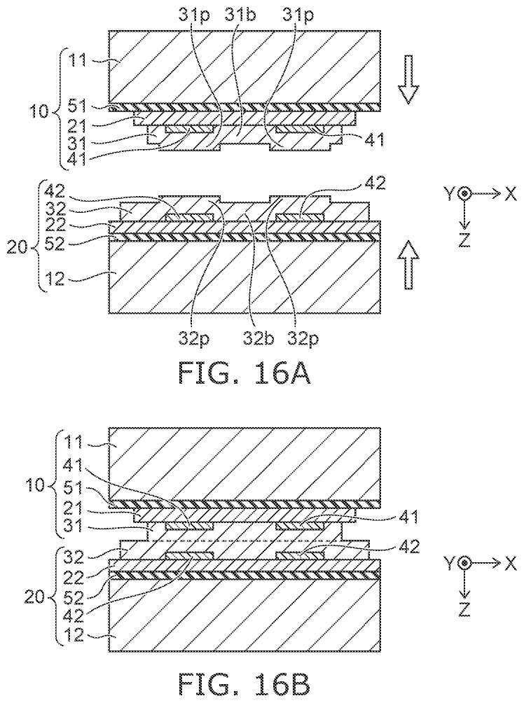

FIGS. 16A and 16B are schematic views illustrating a method for manufacturing another electronic device according to the embodiment.

FIGS. 16A and 16B are schematic cross-sectional views in order of the processes, illustrating bonding between the first structure body 10 and the second structure body 20. In the example as illustrated in FIG. 16A, one first bonding electrode 31 of the first structure body 10 includes one first electrode part 31b and multiple first protruding parts 31p before the bonding process. Multiple first hard parts 41 that correspond to the multiple first protruding parts 31p are included in the one first bonding electrode 31.

Similarly, in the example as illustrated in FIG. 16A, one second bonding electrode 32 of the second structure body 20 includes one second electrode part 32b and multiple second protruding parts 32p before the bonding process. Multiple second hard parts 42 that correspond to the multiple second protruding parts 32p are included in the one second bonding electrode 32.

The first bonding electrode 31 and the second bonding electrode 32 are bonded as illustrated in FIG. 16B. At this time, for example, at least a portion of each first protruding part 31p is positioned to overlap at least a portion of one of the second protruding parts 32p in the Z-direction. For example, at least a portion of each first hard part 41 is positioned to overlap at least a portion of each second hard part 42 in the Z-direction.

Thus, the one first bonding electrode 31 may include multiple first hard parts 41 and multiple first protruding parts 31p. One second bonding electrode 32 may include multiple second hard parts 42 and multiple second protruding parts 32p. In such a case as well, because the bonding electrodes include the protruding parts, the first bonding electrode 31 and the second bonding electrode 32 can be easily bonded.

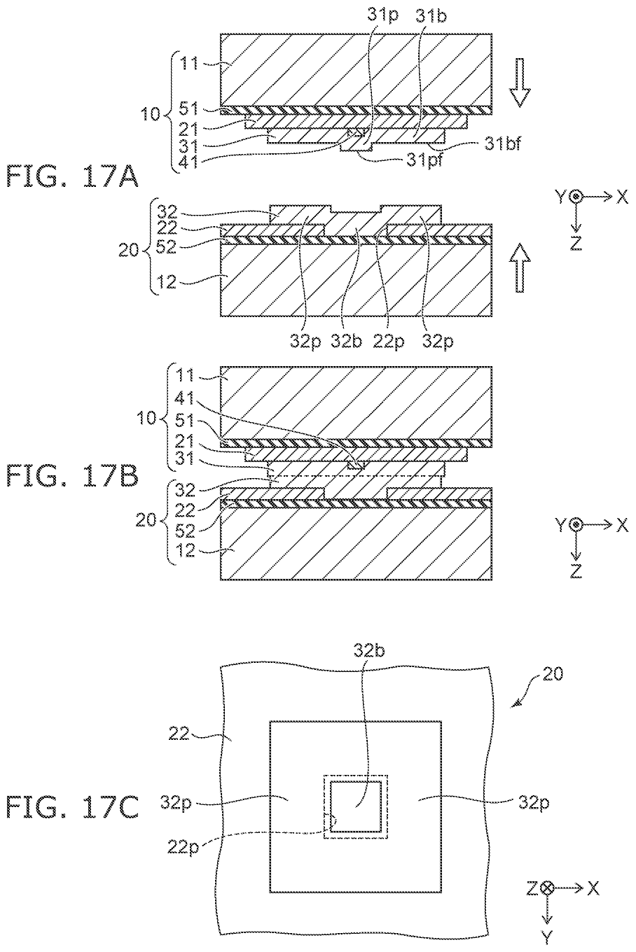

FIGS. 17A to 17C are schematic views illustrating a method for manufacturing another electronic device according to the embodiment.

FIGS. 17A and 17B are schematic cross-sectional views in order of the processes, illustrating bonding between the first structure body 10 and the second structure body 20. FIG. 17C is a schematic plan view illustrating the second structure body 20 before the bonding process. The first structure body 10 illustrated in FIG. 17A may be similar to the first structure body 10 shown in FIG. 13A.

A recess 22p (an opening) is provided in the second wiring part 22 of the second structure body 20. For example, as illustrated in FIG. 17C, the recess 22p is a rectangular opening provided in the second wiring part 22.

As illustrated in FIGS. 17A and 17C, the second bonding electrode 32 includes the second electrode part 32b (the recess) and the second protruding part 32p before the bonding process. In the example, the second electrode part 32b is located in the recess 22p of the second wiring part 22. A portion of the second electrode part 32b is located inside the recess 22p. In other words, the rectangular recess of the second bonding electrode 32 corresponding to the recess 22p of the second wiring part 22 is the second electrode part 32b. The second protruding part 32p is located on the second wiring part 22 around the recess 22p. The second protruding part 32p surrounds the second electrode part 32b when viewed in plan in FIG. 17C.

In the example as illustrated in FIG. 17A, the first protruding part 31p and the second electrode part 32b are arranged to overlap in the Z-direction; and the first electrode part 31b and the second protruding part 32p are arranged to overlap in the Z-direction. In the bonding process, for example, the first protruding part 31p and the second electrode part 32b (the recess) contact each other; and the second protruding part 32p and the first electrode part 31b contact each other. In other words, the bonding process includes causing the first protruding part 31p and the recess of the second bonding electrode 32 (the second electrode part 32b) to contact each other in the Z-direction.

When forming the recess 22p, for example, a conductive layer that is used to form the second wiring part 22 is formed on the second base body 12, after which the conductive layer is patterned by lithography, etching, etc. The second wiring part 22 that includes the recess 22p can be formed thereby. Subsequently, a metal layer that is used to form the second bonding electrode 32 is formed and patterned on the second wiring part 22 that includes the recess 22p. Thereby, an unevenness that corresponds to the unevenness of the second wiring part 22 can be formed in the second bonding electrode 32. Thus, an unevenness (i.e., the second electrode part 32b and the second protruding part 32p) may be formed in the second bonding electrode 32 by patterning the second wiring part 22. In such a case as well, because the bonding electrode includes the protruding part, the first bonding electrode 31 and the second bonding electrode 32 can be easily bonded.

Although the second wiring part 22 is patterned in the example, the unevenness (i.e., the first electrode part 31b and the first protruding part 31p) according to the embodiment may be formed in the first bonding electrode 31 by patterning the first wiring part 21. The position and shape of the unevenness to be formed is not limited to the description above and can be modified as appropriate. For example, the recess (the opening) that is provided in the first or second wiring part 21 or 22 is not limited to rectangular and may be circular, polygonal, etc., and may be positioned at the center or end portion of the bonding electrode.

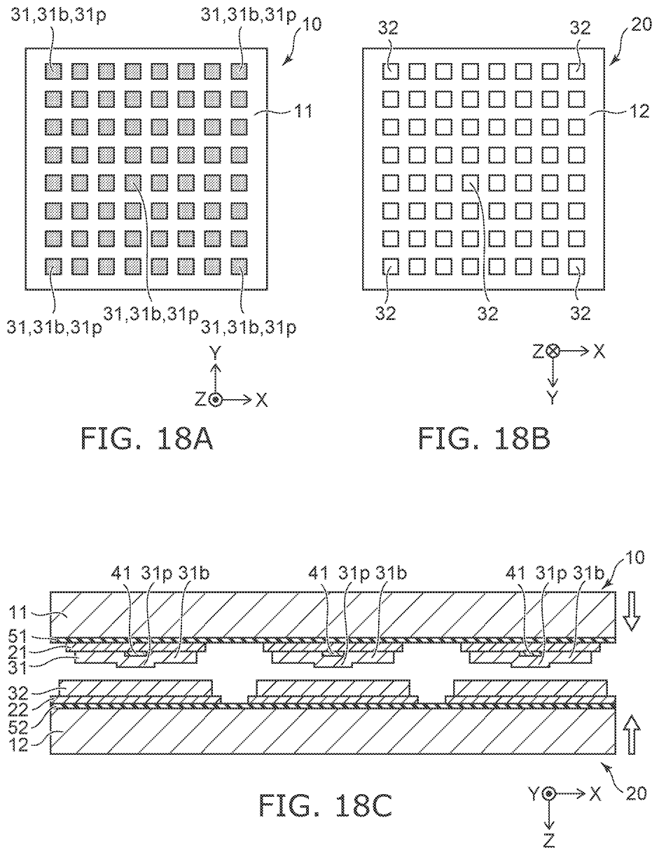

FIGS. 18A to 18C are schematic views illustrating a method for manufacturing another electronic device according to the embodiment.

These drawings illustrate the method for manufacturing the electronic device 105 described with reference to FIGS. 6A and 6B. In other words, the first structure body 10 and the second structure body 20 each are semiconductor substrates (chips). FIGS. 18A and 18B are schematic plan views respectively illustrating the first structure body 10 and the second structure body 20 before the bonding process. Some of the components are not illustrated to simplify the illustration for easier viewing in FIGS. 18A and 18B. FIG. 18C is a schematic cross-sectional view illustrating the bonding process.

In the first structure body 10 illustrated in FIG. 18A, each first bonding electrode 31 includes the first electrode part 31b and the first protruding part 31p. Each first hard part 41 is positioned between the first protruding part 31p and the first base body 11 (the first wiring part 21). Such a first bonding electrode can be formed similarly to the manufacturing method described above. In other words, the first hard part 41 is formed by patterning the first hard layer 41f. The first bonding electrode 31 is formed by forming and patterning the metal layer 31f on the first hard part 41.

In the second structure body 20 illustrated in FIG. 18B, the second bonding electrodes 32 do not include the second protruding part. However, similarly to FIG. 14A or FIG. 15A, the second protruding part also may be included in the second bonding electrodes 32 of FIG. 18B.

As illustrated in FIG. 18C, the first structure body 10 and the second structure body 20 are overlaid so that the first bonding electrode 31 and the second bonding electrode 32 face each other; and the first bonding electrode 31 and the second bonding electrode 32 are compression-bonded (the bonding process). In the bonding process, first, the multiple first protruding parts 31p and the multiple second bonding electrodes 32 are brought into contact and pressurized. Subsequently, the multiple first electrode parts 31b and the multiple second bonding electrodes 32 contact and are bonded.

Thus, the first protruding part 31p may be included in each of the multiple first bonding electrodes 31. For example, the contact area with the second bonding electrode 32 in each first bonding electrode 31 can be reduced thereby, and the first bonding electrode 31 and the second bonding electrode 32 can be easily bonded.

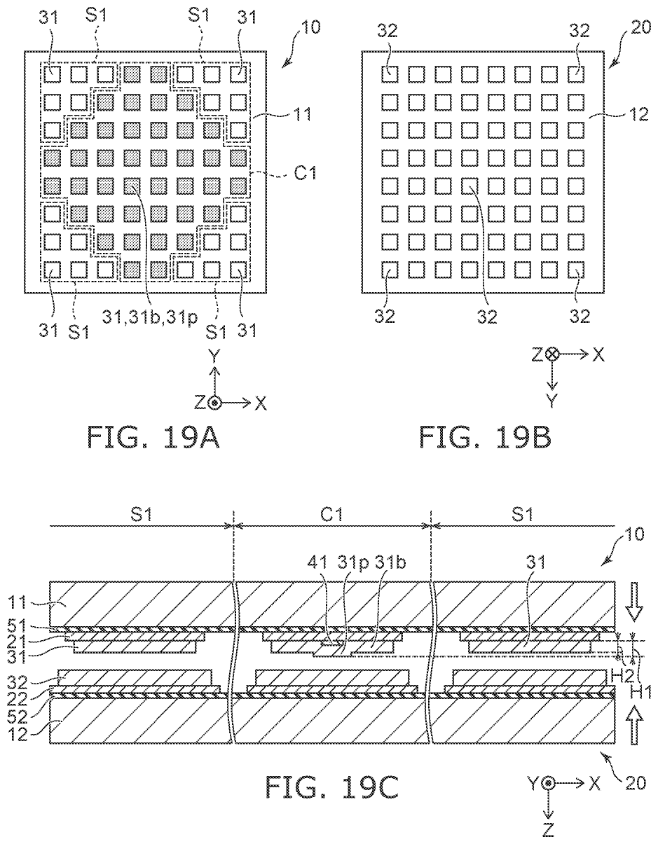

FIGS. 19A to 19C are schematic views illustrating a method for manufacturing another electronic device according to the embodiment.

These drawings illustrate a method for manufacturing the electronic device 106 described with reference to FIGS. 7A to 7C. FIGS. 19A and 19B are schematic plan views respectively illustrating the first structure body 10 and the second structure body 20 before the bonding process. Some of the components are not illustrated to simplify the illustration for easier viewing in FIGS. 19A and 19B. FIG. 19C is a schematic cross-sectional view illustrating the bonding process.

As illustrated in FIG. 19A, the first base body 11 includes the central region C1 and the outer region S1 positioned outward of the central region C1 in a plane perpendicular to the Z-direction. In the example, multiple first hard parts 41 are located in the central region C1, but the first hard part 41 is not included in the outer region S1.

The first bonding electrode 31 is located in each of the central region C1 and the outer region S1. The multiple first bonding electrodes 31 include an electrode (a first convex electrode) that includes the first protruding part 31p and an electrode (a first non-convex electrode) that does not include the first protruding part 31p. The first bonding electrode 31 that includes the first protruding part 31p is located in the central region C1 but is not located in the outer region S1. The first bonding electrode 31 that does not include the first protruding part 31p is located in the outer region S1 but is not located in the central region C1.

As illustrated in FIG. 19C, a height H1 of the first convex electrode (the first bonding electrode 31 located in the central region C1) is greater than a height H2 of the first non-convex electrode (the first bonding electrode 31 located in the outer region S1) before the bonding process. Therefore, the first convex electrode protrudes further toward the second base body 12 side than the first non-convex electrode. The height of the electrode is the length of the electrode along the Z-direction. In other words, the height of the first bonding electrode 31 is the distance from the first wiring part 21 to the tip surface of the first bonding electrode 31.

The hard part formation process of forming the first hard part 41 includes forming the first hard layer 41f on the central region C1 and the outer region S1 and selectively forming the multiple first hard parts in the central region C1 by patterning the first hard layer 41f. In other words, by the patterning, the portion of the first hard layer 41f located in the outer region S1 and a portion of the central region C1 is removed, and the portion of the first hard layer 41f located on a portion of the first wiring part 21 in the central region C1 remains.

The electrode formation process of forming the first bonding electrode 31 includes forming the metal layer 31f on the central region C1 and the outer region S1. Then, the electrode formation process selectively forms the multiple first bonding electrodes 31 in each of the central region C1 and the outer region S1 by patterning the metal layer 31f.

The second protruding part is not included in the second bonding electrodes 32 in the second structure body 20 illustrated in FIG. 19B. For example, the heights of all of the second bonding electrodes 32 are substantially the same.

As illustrated in FIG. 19C, the first structure body 10 and the second structure body 20 are overlaid so that the first bonding electrode 31 and the second bonding electrode 32 face each other; and the first bonding electrode 31 and the second bonding electrode 32 are compression-bonded (the bonding process). In the bonding process, first, the first protruding parts 31p and the second bonding electrodes 32 in the central region C1 are brought into contact and pressurized. Subsequently, the first electrode parts 31b and the second bonding electrodes 32 in the central region C1 contact and are bonded. The first bonding electrodes 31 and the second bonding electrodes 32 in the outer region S1 contact and are bonded.

According to the embodiment, the contact area with the second bonding electrode 32 of each first bonding electrode 31 in the central region C1 can be reduced, and the first bonding electrode 31 and the second bonding electrode 32 can be easily bonded. The hard part formation process includes forming the first hard part 41 by patterning the first hard layer 41f. Thereby, the first hard part 41 and the first protruding part 31p can be selectively formed in the central region C1.

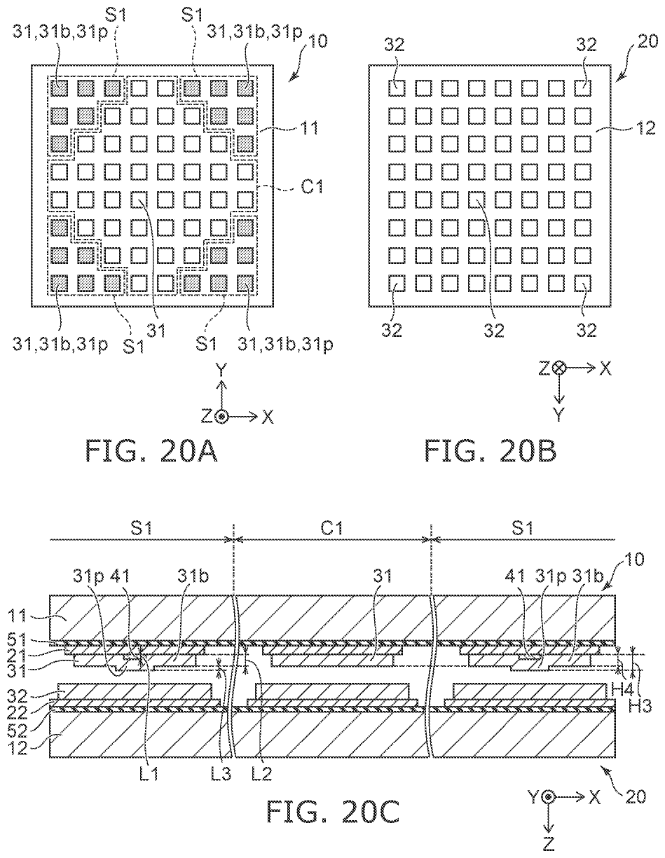

FIGS. 20A to 20C are schematic views illustrating a method for manufacturing another electronic device according to the embodiment.

These drawings illustrate the method for manufacturing the electronic device 107 described with reference to FIGS. 8A to 8C. FIGS. 20A and 20B are schematic plan views respectively illustrating the first structure body 10 and the second structure body 20 before the bonding process. Some of the components are not illustrated to simplify the illustration for easier viewing in FIGS. 20A and 20B. FIG. 20C is a schematic cross-sectional view illustrating the bonding process.

As illustrated in FIG. 20A, the first base body 11 includes the central region C1 and the outer region S1 positioned outward of the central region C1 in a plane perpendicular to the Z-direction. In the example, multiple first hard parts 41 are located in the outer region S1, but the first hard part 41 is not located in the central region C1.

The first bonding electrode 31 is located in each of the central region C1 and the outer region S1. The multiple first bonding electrodes 31 include an electrode (a convex electrode) that includes the first protruding part 31p and an electrode (a non-convex electrode) that does not include the first protruding part 31p. The first bonding electrode 31 that includes the first protruding part 31p is located in the outer region S1 but is not located in the central region C1. The first bonding electrode 31 that does not include the first protruding part 31p is located in the central region C1 but is not located in the outer region S1.

As illustrated in FIG. 20C, a height H3 of the convex electrode (the first bonding electrode 31 located in the outer region S1) is greater than a height H4 of the non-convex electrode (the first bonding electrode 31 located in the central region C1) before the bonding process. Therefore, the convex electrode protrudes further toward the second base body 12 side than the non-convex electrode.

The hard part formation process of forming the first hard part 41 includes forming the first hard layer 41f on the central region C1 and the outer region S1 and selectively forming multiple first hard parts in the outer region S1 by patterning the first hard layer 41f. In other words, by the patterning, the portion of the first hard layer 41f that is located in the central region C1 and in part of the outer region S1 is removed, and the portion of the first hard layer 41f that is located on part of the first wiring part 21 in the outer region S1 remains.

The electrode formation process of forming the first bonding electrode 31 includes forming the metal layer 31f on the central region C1 and the outer region S1. Then, the electrode formation process selectively forms the multiple first bonding electrodes 31 in each of the central region C1 and the outer region S1 by patterning the metal layer 31f.

The second structure body 20 illustrated in FIG. 20B is similar to the description of the second structure body 20 of FIG. 19B.

In the bonding process, first, the first protruding parts 31p and the second bonding electrodes 32 in the outer region S1 are brought into contact and pressurized. Subsequently, the first electrode parts 31b and the second bonding electrodes 32 in the outer region S1 contact and are bonded. The first bonding electrodes 31 and the second bonding electrodes 32 in the central region C1 contact and are bonded.

According to the embodiment, the contact area with the second bonding electrode 32 of each first bonding electrode 31 in the outer region S1 can be reduced, and the first bonding electrode 31 and the second bonding electrode 32 can be easily bonded. The hard part formation process includes forming the first hard part 41 by patterning the first hard layer 41f. Thereby, the first hard part 41 and the first protruding part 31p can be selectively formed in the outer region S1.

A length L1 along the Z-direction of the first hard part 41 may be less than a length L2 along the Z-direction of the first electrode part 31b. In other words, a length L3 along the Z-direction of the first protruding part 31p may be less than the length L2 along the Z-direction of the first electrode part 31b.

The length L1 along the Z-direction of the first hard part 41 may be greater than the length L2 along the Z-direction of the first electrode part 31b. In other words, the length L3 along the Z-direction of the first protruding part 31p may be greater than the length L2 along the Z-direction of the first electrode part 31b. In such a case, for example, the first hard part 41 easily functions as a stopper.

The first structure body 10 and the second structure body 20 are chips in the description of the manufacturing method described above. However, the first structure body 10 and the second structure body 20 each may be wafers. In such a case, for example, the electronic device 108 (FIGS. 9A and 9B), the electronic device 109 (FIGS. 10A to 10C), or the electronic device 110 (FIG. 11) can be manufactured by a similar manufacturing method.

For example, according to the method for manufacturing the electronic device 109 illustrated in FIGS. 10A to 10C, in the first structure body 10 before bonding, the first bonding electrode 31 of the central region C2 is a convex electrode, and the first bonding electrode 31 of the outer region S2 is a non-convex electrode. For example, according to the method for manufacturing the electronic device 110 illustrated in FIG. 11, in the first structure body 10 before bonding, the first bonding electrode 31 of the central region C2 is a non-convex electrode, and the first bonding electrode 31 of the outer region S2 is a convex electrode.

Chip to chip bonding or wafer to wafer bonding is illustrated in the description above. However, embodiments may include bonding between a chip and a wafer.

FIG. 21 is a schematic cross-sectional view illustrating another electronic device according to the embodiment.

The electronic device 111 illustrated in FIG. 21 includes the first structure body 10 and the second structure body 20. The first structure body 10 includes the first base body 11, the first wiring part 21, the first bonding electrode 31, and the first element part 61. In the example, the first structure body 10 is a sensor element that is formed by a MEMS process and detects an acceleration or an angular velocity. For example, the first element part 61 includes an electrode of which the position is displaced by an acceleration or the like arising in the first structure body. For example, the electrostatic capacitance of the electrode is changed by the displacement of the electrode. The acceleration or the like can be detected by detecting the electrostatic capacitance. The first wiring part 21 is electrically connected with the electrodes of the first element part 61.

The second structure body 20 includes the second base body 12, the second wiring part 22, the second bonding electrode 32, and the second element part 62. In the example, the second structure body 20 is an LSI (Large-Scale Integration) chip. For example, the second element part 62 includes an electrical element such as a field-effect transistor, etc. For example, the second base body 12 includes a semiconductor substrate 12a, and a multilevel interconnect part 12b (an inter-layer insulating film) formed on the semiconductor substrate 12a. The electrical element such as the field-effect transistor or the like is included in the semiconductor substrate 12a. The second wiring part 22 includes a wiring layer 22a that is located on the second base body 12 and a multilevel interconnect layer 22b that is located in the multilevel interconnect part 12b. The wiring layer 22a is electrically connected with the second element part 62 via the multilevel interconnect layer 22b. The second wiring part 22 may include an electrode pad part 22c. For example, electrical power and/or a signal is supplied to the LSI chip from the outside via the electrode pad part 22c.

The second bonding electrode 32 is bonded with the first bonding electrode 31. Thereby, the first structure body 10 that is a sensor element formed by a MEMS process is bonded with the second structure body 20 that is an LSI chip. For example, the electrical signal that is detected by the first element part 61 is input to the second element part 62 via the first wiring part 21, the first bonding electrode 31, the second bonding electrode 32, and the second wiring part (the wiring layer 22a and the multilevel interconnect layer 22b). The signal that is detected by the first element part 61 can be processed in the second element part 62. Interconnects, etc., are not illustrated.

For example, the first hard part 41 is located in at least a portion of the first bonding electrode 31 or the first wiring part 21. For example, at least a portion of the first bonding electrode 31 is a convex electrode before the bonding process. For example, the second hard part 42 is located in at least a portion of the second bonding electrode 32 or the second wiring part 22. For example, at least a portion of the second bonding electrode 32 is a convex electrode before the bonding process. Similarly to electronic device described above, the yield of the electronic device 111 also can be increased thereby.

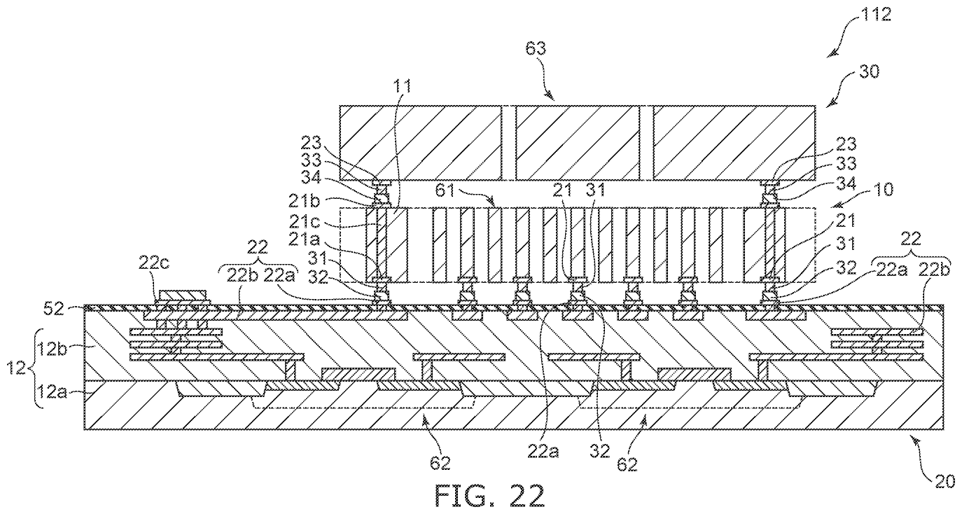

FIG. 22 is a schematic cross-sectional view illustrating another electronic device according to the embodiment.

The electronic device 112 illustrated in FIG. 22 includes the first structure body 10, the second structure body 20, and a third structure body 30. The first structure body 10 is positioned between the second structure body 20 and the third structure body 30. The first structure body 10 is connected with the second structure body 20 and connected with the third structure body 30. Thus, the electronic device according to the embodiment may be a device in which the three or more structure bodies (e.g., chips or wafers) are stacked.

The first structure body 10 includes the first base body 11, the first wiring part 21, the first bonding electrode 31, the first element part 61, and a fourth bonding electrode 34. For example, the first base body 11, the first bonding electrode 31, and the first element part 61 are similar to the description of FIG. 21. The first wiring part 21 includes a wiring layer 21a, a wiring layer 21b, and a wiring layer 21c. The wiring layer 21a is located at the second structure body 20 side of the first base body 11. The wiring layer 21b is located at the third structure body 30 side of the first base body. The wiring layer 21c connects the wiring layers 21a and 21c. The wiring layer 21c is, for example, a through-via extending through the first base body 11. The fourth bonding electrode 34 contacts the wiring layer 21b and is electrically connected with the wiring layer 21b.

The second structure body 20 is, for example, an LSI chip similarly to the description of FIG. 21. The first structure body 10 and the second structure body 20 are electrically connected similarly to the description of FIG. 21.

The third structure body 30 includes a third base body 13, a third wiring part 23, a third bonding electrode 33, and a third element part 63. In the example, the third structure body 30 is a MEMS that detects an acceleration or pressure. For example, the third element part 63 includes a weight or a diaphragm that is displaced by pressure or the like applied to the third structure body 30. For example, the third element part 63 includes a sensor part (e.g., a strain gauge) that detects the displacement of the weight or the diaphragm. The sensor part may be an electrode that uses electrostatic capacitance to detect the displacement of the weight or the diaphragm. The third wiring part 23 is electrically connected with the sensor part of the third element part 63. The third bonding electrode 33 contacts the third wiring part 23 and is electrically connected with the third wiring part 23.

The third bonding electrode 33 is bonded with the fourth bonding electrode 34. Thereby, the third structure body 30 is bonded with the first structure body 10. The third structure body 30, i.e., the MEMS, is electrically connected with the second structure body 20, i.e., the LSI chip, via the first base body 11. For example, an electrical signal that is detected by the third element part 63 is input to the second element part 62 via the third wiring part 23, the third bonding electrode 33, the fourth bonding electrode 34, the first wiring part 21 (the wiring layers 21b, 21c, and 21a), the first bonding electrode 31, the second bonding electrode 32, and the second wiring part (the wiring layer 22a and the multilevel interconnect layer 22b). The signal that is detected by the third element part 63 can be processed by the second element part 62.

For example, similarly to the first hard part 41, a hard part is located at the third bonding electrode 33 or the third wiring part 23. Or, similarly to the first hard part 41, a hard part is located at the fourth bonding electrode 34 or the wiring layer 21b. For example, at least a portion of the third or fourth bonding electrode 33 or 34 is a convex electrode before bonding. Similarly to the electronic device described above, the yield of the electronic device 112 also can be increased thereby.

An electronic device and a method for manufacturing an electronic device according to embodiments are described above. More specific examples will now be described.

In recent years, three-dimensional stacking technology is being used to bond semiconductor devices having different functions to form products that would be technologically difficult to realize using a single wafer process. The bonding is performed using a so-called micro-bump structure (connection electrodes).

For example, multiple Au bonding electrodes that have a height of about 1 to 2 μm and a size of about 3 to 5 μm are formed on an LSI substrate (in which a control circuit, etc., are formed). The method for forming the Au bonding electrodes includes forming Au as electrodes by plating after patterning a resist on the wiring. On the other hand, Au bonding electrodes are similarly formed on another substrate that has, for example, the function of a MEMS sensor. After the substrates are thinned and diced into chips, the bonding electrodes are caused to face each other and are bonded by thermal compression bonding. Semiconductor chips that have a combination of a MEMS sensor function and a control function can be formed as one body.

However, when stress (a load) is applied to the chip when bonding in the thermal compression bonding, stress concentration occurs at the chip peripheral part, and discrepancies easily occur in which only the peripheral part is bonded and the central part is not bonded. When the stress of the compression bonding is increased, the deformation of the Au electrodes for bonding is increased, and discrepancies easily occur in which the Au electrodes jut from the interconnect and cause a short with another electrically isolated interconnect. Also, when bonding is performed in the wafer state without singulating into chips, there are cases where the yield of the bonding (short defects and open defects) is different between the peripheral part and the central part of the wafer.

In addition to the effects of the stress and load when bonding the substrates or chips, electrodes that are formed by plating may have electrode height fluctuation, i.e., differences in the plating growth in the chip or wafer surface due to the plating current density. Discrepancies easily occur in bonding similarly to the description above in which the bonding is partially incomplete and the yield degrades.

In contrast, according to the example, a step is formed in any location of the surface portion of the bonding electrode to partially change the height of the bonding electrode, thereby more reliably bonding the electrodes to each other in the bonding process of thermal compression bonding, etc. Also, a stopper structure is formed of the underlying film (of the electrode) for forming the step structure, thereby suppressing deformation of the Au electrode even when excessive pressure is applied when bonding; therefore, shorts of the wiring parts can be suppressed.

According to the example, the multiple micro-bump structures (bonding electrodes) that are formed on one or multiple wafers, chips, or substrates (e.g., a wafer, chip, or substrate in which a CMOS circuit is formed, a wafer, chip, or substrate in which a sensor or the like is formed, a wafer, chip, or substrate in which connection wiring is formed, etc.) have different bonding electrode heights among locations in the wafer, chip, or substrate. Bonding electrodes that have different heights have multiple upper surfaces of different heights. A material that has greater hardness and rigidity than the material of the bonding electrode is formed in the layer under the bonding electrode on or under the interconnect to which the bonding electrode is connected. The example also includes wafers, chips, or substrates bonded using the bonding electrodes.

### Example 1

It is assumed that a substrate (e.g., an LSI substrate) that includes drive and detection circuits formed by a CMOS process on a silicon substrate and a substrate (e.g., a MEMS substrate) in which a sensor device is formed by a MEMS process are made into chips and then bonded. The method for forming the bonding electrode having the partially different heights (called the convex electrode for convenience) according to the embodiment is similar when applying to either substrate. It is therefore assumed in the following description that a convex electrode is formed at the LSI substrate side.

First, a drive circuit, an arithmetic circuit, etc., are formed on the silicon substrate by a general CMOS process, etc. The uppermost layer of the wiring layer on which the bonding electrode is formed has a pattern that matches the MEMS part to be connected. For example, the interconnects of the uppermost layer are formed of Al interconnects.

A TEOS film is formed in a pattern as a spacer on the Al interconnects at the locations at which the convex electrodes are to be formed. For example, after forming the Al interconnects, a TEOS film of about 100 nm to 1 μm is formed over the entire surface. The TEOS film is patterned by performing lithography using a resist mask and anisotropic etching to form a TEOS pattern on the Al interconnects corresponding to the locations at which the convex electrodes are to be formed.

The arrangement pattern compensates the fluctuation of the stress and load distributions due to the bonding apparatuses and methods that are used. For example, when chips are bonded to each other, the pressing load and stress easily concentrate at the peripheral part of the chip. Therefore, the convex bonding electrodes are located mainly at the central part of the chip. Accordingly, the TEOS spacers are located at the central part of the chip. Conversely, for an apparatus in which the pressing load easily concentrates at the chip central part, it is effective to position the convex electrodes at the chip peripheral part. Therefore, the spacers of the TEOS film are formed to correspond to the electrodes corresponding to the periphery of the chip. For example, the shape of the spacer itself is such that the size of the TEOS is 1 μm square when the size of the bonding electrode is 5 μm square.

Then, Ti/Pd is formed over the entire surface as a barrier metal. For example, the thickness of the Ti/Pd is 100/50 nm. For example, the Ti/Pd is formed by sputtering. Then, a pattern for forming the bonding electrodes is formed by lithography. Plating is used to form Au in the locations patterned by the lithography. For example, the thickness of the Au is 1 to 2 μm. Then, after removing the resist, the bonding electrodes of Au can be formed by removing the barrier metal by a wet method. The Au electrode upper surfaces are high at the locations of the TEOS film. Instead of a single-layer spacer, the spacer can be formed in a convex staircase shape by forming a first spacer, then forming a TEOS thin film again, and then by patterning by lithography and etching.

Similarly for the MEMS substrate side as well, Au bonding electrodes are formed on the wiring layer where the bonding electrodes are to be located. Here, because a convex shape is not used, the bonding electrodes are formed by directly forming the barrier metal on the wiring layer without forming the TEOS film.

The wafers of the LSI substrate and the MEMS substrate are thinned to the desired thicknesses and then diced into chips. Subsequently, the bonding surfaces are caused to face each other, and the chips are bonded. Normally, one of the wafers is placed on a fixed stage, the other wafer is clamped to a movable stage, and the movable stage is move toward the fixed stage to cause contact between the bonding surfaces (the Au bonding electrodes). The alignment between the electrodes is performed by a bonding apparatus, and there are many cases where alignment marks are made in the chips, and the bonding apparatus performs the alignment by optically reading the fine movement of the stage. The bonding electrodes are bonded to each other by thermal compression by applying a load to one or both of the stages. For Au, the stage is heated to about 200° C. to 400° C.

Because the surface area of the convex location is less than the surface area of the entire bonding electrode, the apparent pressure at the location of the initial contact is large, and the Au electrode is easily deformed. Therefore, the electrical yield is easily improved.

Thus, a device can be formed in which an LSI drive and detection circuit and a MEMS sensor part are integrated.

### Example 2

According to an example 2, it is assumed that wafers are stacked together.

The method for forming the bonding electrode is similar to the example 1, but the locations of the convex electrodes are at the central part (the central region) or the peripheral part (the outer region) of the wafer. Because the wafer bonding apparatus that is used causes a pressing load distribution at the periphery or center of the wafer, the fluctuation of the pressing load in the wafer surface corresponds to the bonding electrode yield.

In this case (when the pressing load is large at the wafer peripheral part), the spacers that are formed at the locations at which the convex electrodes are located, i.e., on the interconnects, are not formed on all of the chips with the same pattern, but are formed, for example, only on the chips at the wafer central part.

Similarly to the example 1, after forming, for example, the TEOS film as spacers on the interconnects, the TEOS film is patterned using a resist mask and anisotropic etching; however, at this time, lithography is performed for only the resist mask at the wafer central part and not for the peripheral part. When lithography is performed using a stepper, the chips that are exposed can be limited, and the resist can remain at the periphery while exposing only the chips at the central part of the wafer. In the case of a full exposure apparatus, data is generated so that the pattern of the spacer film is formed only at the center when making the reticle (photomask) pattern (however, although a stepper or the like may cause the pattern to be cut off at the wafer periphery, such locations do not operate as final products).

Similarly to the example 1, for example, the barrier metal is formed over the entire surface of the wiring layer at the central part of the wafer after forming the TEOS film spacers. The lithography for forming the Au bonding electrodes is similar to the example 1 and uses the same pattern in the wafer surface (having a similar cut off pattern).

Similarly to the example 1, the Au bonding electrodes can be formed by processing such as plating, etc., and by performing resist removal, etching of the barrier metal, etc. At this time, convex electrodes are formed at the central part of the wafer.

After thinning the wafers to the desired thicknesses, the wafers to be bonded are placed on stages, and the wafer bonding is performed by applying a load. After bonding, the stacked devices can be formed by dicing into chips.

When the pressing load fluctuation of the wafer bonding apparatus causes the pressing load to be large at the central part so that the bonding yield at the wafer peripheral part is degraded (opens occur), the TEOS spacer film is formed at the wafer peripheral part by patterning.

### Example 3

According to an example 3, the spacer is formed in a layer under the wiring layer.

Before forming the wiring layer, e.g., the Al interconnects, a silicon nitride film is formed on the inter-layer film, and spacers are formed by resist patterning and anisotropic etching only at the locations at which the convex electrodes are to be formed. Or, the inter-layer film itself is patterned by resist patterning and etching to form steps corresponding to the spacers in the desired regions. Subsequently, the wiring layer is formed by forming Al over the entire surface and by patterning. At this time, the patterning of the step shapes is performed at the desired locations of the wiring layer.

Then, a barrier metal is formed over the entire surface, and a resist is used to pattern the locations at which the Au bonding electrodes are to be formed. Au is formed by plating, and the bonding electrodes are formed by removing the resist and the unnecessary barrier metal. Because the spacers or steps are under the wiring layer, the step-shaped bonding electrodes are formed in the desired regions as in the example 1.

### Example 4

According to an example 4, the spacers are used as a stopper structure.

Although bonding electrode yield defects include open defects in which the bonding electrodes do not contact each other due to the pressing load distribution and stress distribution of the bonding apparatus, on the other hand, there are cases where short defects occur between the wiring layer on which the electrodes are located because the bonding electrode material deforms more than expected due to excessive pressing because the pressing amount (the load and stress) was increased to prevent the open defects. In such a case, the shorts due to the deformation of the electrode material can be avoided by preventing the substrates from approaching each other more than necessary. The example controls the distance between the bonding substrates by utilizing the fact that the spacer portions do not easily deform even when the stress of the bonding is applied.

The convex electrodes are formed similarly to the example 1 or 2. When the electrodes to be bonded are compression-bonded to each other, the Au, i.e., the electrode material, is ductile and deforms, while the TEOS film, i.e., the brittle material, does not deform; therefore, the spacer TEOS film acts as a stopper, and the distance between the bonded devices is maintained by the thickness of the spacer even when the load is large.

At this time, the convex electrodes are used to intentionally increase the bonding load and stress to increase the electrode deformation; it is therefore desirable to increase the spacer thickness or to form the spacer in both of the devices to be bonded. The convex electrodes of the arrangement may be reduced as long as the substrates are not deformed. The bonding process is applicable to either wafers or chips. The electrodes with spacers may be located only at locations when the load is applied more.

### Example 5

Although misalignment may be undesirably caused by the pressing load applied when bonding, according to the example, a structure that surrounds the spacer prevents misalignment. In such a case, spacers are formed on both of the substrates to be bonded. The spacer at one side is patterned in a dot configuration, and the facing side is patterned in a square frame shape (a rectangle with an opening or recess at the center). The dot configuration spacer is enclosed with the square-frame-shaped spacer when bonding. For example, an anchor effect can suppress misalignment even when a force acts to cause the substrate to misalign when applying the load when bonding.

The invention is not limited to the above examples; and various modifications can be implemented to the extent that the purport of the invention is included.

The method for forming the bonding electrode may be plating instead of sputtering. In such a case, the bonding electrode is formed by forming a bonding electrode material (e.g., Au) over the entire surface and then by performing lithography and etching to obtain the desired electrode shape. The spacer film is formed before sputtering the bonding electrode material.

Dummy electrodes that do not electrically contribute to the bonding (e.g., electrodes that are not electrically connected with the element part) may be included and may have convex shapes. In particular, when the pressure in the substrate bonding is large, the uniformity of the electrical bonding electrodes can be increased by positioning stress-bearing dummy electrodes separately from the electrically-bonding electrodes; and the bonding yield can be increased.

Convex electrodes may be formed over the entire wafer surface (at all of the bonding electrodes) when chips are bonded to each other and when wafers are bonded to each other. In such a case, because the surface area of the convex portions is small, the contact area when bonding (at the initial contact) can be reduced so that sufficient bonding can be performed even with a small load. For example, even when the pressing load and stress when bonding has a distribution, the bonding yield can be increased by reducing the effects of the distribution.

Although two types of substrates or chips are adhered when bonding, three or more types of substrates or chips may be bonded by bonding another substrate on substrates that are already bonded, etc. In such a case (when the surface areas of the bonding electrodes are the same, i.e., the apparent pressing loads applied to the bonding electrodes are about the same), if the load applied to the chips or wafers in the bonding after the initial bonding is not less than the initial load, there is a risk of shorts due to deformation of the initial bonding parts due to the subsequent load further deforming the bonding parts that were initially bonded; on the other hand, sufficient bonding may occur at the locations that are subsequently bonded. Therefore, by using the convex electrode described above as the bonding electrode of the second bonding, the apparent contact area of the bonding can be reduced, thereby reducing the apparent pressing load and stress. Therefore, for example, the thermal compression bonding begins from the second bonding, thereby reducing the effects on the initial bonding locations.

Embodiments also are applicable when adhering multiple chips on one substrate. Substrates (wafers or chips) to be bonded can include at least one of a CMOS circuit (LSI) having a control function, a MEMS electrode structure including electrodes and through-holes, inertial MEMS such as a MEMS acceleration sensor, a gyroscope, or the like, a sensor element such as a pressure sensor or the like, a memory element such as DRAM, nonvolatile memory, or the like, a passive element such as a CMOS sensor or the like, an element having a power control function, an optical element, a high frequency element such as RF-MEMS or the like, an element formed of a compound semiconductor, an element having a wiring function such as a connection layer, a bonding pad for connection to the outside, etc. However, the functions of the substrates (wafers or chips) to be bonded are not limited.

When the substrates (wafers or chips) to be bonded are wafers, the size may be 300 mm, and even 200 mm or less. The chip size is not limited.

According to embodiments, an electronic device and a method for manufacturing an electronic device that can increase the yield can be provided.

In this specification, being “electrically connected” includes not only the case of being connected in direct contact, but also the case of being connected via another conductive member, etc.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in electronic devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all electronic devices practicable by an appropriate design modification by one skilled in the art based on the electronic devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic device, comprising:
a first structure body including
a first base body,
a first wiring part located at the first base body,
a first bonding electrode electrically connected with the first wiring part, and
a first hard part; and
a second structure body including
a second base body,
a second wiring part located at the second base body, and
a second bonding electrode electrically connected with the second wiring part,
the first bonding electrode and the second bonding electrode being bonded to each other between the first base body and the second base body,
the first hard part being located between the first base body and the second base body,
the first hard part being positioned within an area in which the first bonding electrode is located when viewed along a first direction,
the first direction being from the first base body toward the first bonding electrode,
the first hard part having a higher hardness than the first bonding electrode.

2. The device according to claim 1, wherein
the first hard part is located between the first bonding electrode and the first wiring part.

3. The device according to claim 1, wherein
the second structure body includes a second hard part located between the first base body and the second base body,
the second hard part is positioned within an area in which the second bonding electrode is located when viewed along the first direction, and
the second hard part has a higher hardness than the second bonding electrode.

4. The device according to claim 3, wherein
at least a portion of the first hard part overlaps at least a portion of the second hard part in the first direction.

5. The device according to claim 3, wherein
at least a portion of the first hard part is positioned between a portion of the second hard part and another portion of the second hard part when viewed along the first direction.

6. The device according to claim 1, wherein
a plurality of the first bonding electrodes, a plurality of the second bonding electrodes, and a plurality of the first hard parts are included, and
the plurality of first hard parts respectively overlaps the plurality of first bonding electrodes when viewed along the first direction.

7. The device according to claim 1, wherein
the first base body includes a central region and an outer region in a plane perpendicular to the first direction,
the outer region is positioned outward of the central region,
a plurality of the second bonding electrodes is included,
a plurality of the first bonding electrodes is located in the central region,
a plurality of the first bonding electrodes is located in the outer region,
a plurality of the first hard parts is located in the central region,
the first hard part is not located in the outer region, and
the plurality of first hard parts respectively overlaps the plurality of first bonding electrodes located in the central region when viewed along the first direction.

8. The device according to claim 1, wherein
the first base body includes a central region and an outer region in a plane perpendicular to the first direction,
the outer region is positioned outward of the central region,
a plurality of the second bonding electrodes is included,
a plurality of the first bonding electrodes is located in the central region,
a plurality of the first bonding electrodes is located in the outer region,
a plurality of the first hard parts is located in the outer region,
the first hard part is not located in the central region, and
the plurality of first hard parts respectively overlaps the plurality of first bonding electrodes located in the outer region when viewed along the first direction.

9. The device according to claim 1, wherein
the first bonding electrode includes at least one selected from the group consisting of gold, aluminum, copper, and iridium, and
the first hard part includes at least one selected from the group consisting of silicon oxide, silicon nitride, tungsten, titanium nitride, palladium, and titanium.

10. The device according to claim 1,
the device further comprising at least one of
a first element part located in the first structure body and electrically connected with the first wiring part, or
a second element part located in the second structure body and electrically connected with the second wiring part,
the first element part including at least one of a transistor, an electrode, a sensor element, a memory element, or a light-emitting element,
the second element part including at least one of a transistor, an electrode, a sensor element, a memory element, or a light-emitting element.

11. A method for manufacturing an electronic device,
the device including:
a first structure body including
a first base body,
a first wiring part located at the first base body, and
at least one first bonding electrode electrically connected with the first wiring part; and
a second structure body including
a second base body,
a second wiring part located at the second base body, and
at least one second bonding electrode electrically connected with the second wiring part,
the method comprising:
a bonding process of bonding the first bonding electrode and the second bonding electrode,
the at least one first bonding electrode including an electrode that includes:
a first electrode part; and
a first protruding part protruding from the first electrode part in a first direction,
the first direction being from the first base body toward the first bonding electrode,
the bonding process including causing the first protruding part and the second bonding electrode to contact in the first direction.

12. The method according to claim 11, wherein
the first electrode part includes a first electrode surface extending along a plane perpendicular to the first direction,
the first protruding part protrudes in the first direction from the first electrode surface, and
the first protruding part includes a first end surface extending along the plane perpendicular to the first direction.

13. The method according to claim 11, wherein
the at least one second bonding electrode includes an electrode that includes:
a second electrode part; and
a second protruding part protruding from the second electrode part in a direction from the second base body toward the second bonding electrode, and
the bonding process causes the second protruding part and the first bonding electrode to contact in the first direction.

14. The method according to claim 11, wherein
the first structure body includes a first hard part located between the first protruding part and the first base body, and
the first hard part has a higher hardness than the first bonding electrode.

15. The method according to claim 14, wherein
the at least one second bonding electrode includes a recess, and
the bonding process includes causing the first protruding part and the recess to contact in the first direction.

16. The method according to claim 14, further comprising:
a hard part formation process that includes
forming a first hard layer on at least a portion of the first base body and the first wiring part, and
forming the first hard part by patterning the first hard layer.

17. The method according to claim 16, wherein
the first base body includes a central region and an outer region in a plane perpendicular to the first direction,
the outer region is positioned outward of the central region, and
the hard part formation process includes:
forming the first hard layer on the central region and the outer region; and
selectively forming the plurality of first hard parts in the central region by patterning the first hard layer.

18. The method according to claim 16, wherein
the first base body includes a central region and an outer region in a plane perpendicular to the first direction,
the outer region is positioned outward of the central region, and
the hard part formation process includes:
forming the first hard layer on the central region and the outer region; and
selectively forming the plurality of first hard parts in the outer region by patterning the first hard layer.

19. The method according to claim 11, wherein
the first base body includes a central region and an outer region in a plane perpendicular to the first direction,
the outer region is positioned outward of the central region,
a plurality of the second bonding electrodes is included,
a plurality of the first bonding electrodes is located in the central region,
a plurality of the first bonding electrodes is located in the outer region,
the electrode that includes the first protruding part is located in the central region, and
before the bonding process, a height of the electrode that includes the first protruding part and is located in the central region is greater than a height of the first bonding electrode that is located in the outer region.

20. The method according to claim 11, wherein
the first base body includes a central region and an outer region in a plane perpendicular to the first direction,
the outer region is positioned outward of the central region,
a plurality of the second bonding electrodes is included,
a plurality of the first bonding electrodes is located in the central region,
a plurality of the first bonding electrodes is located in the outer region,
the electrode that includes the first protruding part is located in the outer region, and
before the bonding process, a height of the electrode that includes the first protruding part and is located in the outer region is greater than a height of the first bonding electrode that is located in the central region.
